(19) United States
(12) Patent Application Publication
(10) Pub. No.: US 2023/0197615 A1
(43) Pub. Date: Jun. 22, 2023

(54) TRANSFORMERS BASED ON BURIED POWER RAIL TECHNOLOGY

(71) Applicant: Intel Corporation, Santa Clara, CA (US)

(72) Inventors: Peter Baumgartner, Munich (DE); Bernd Waidhas, Pettendorf (DE); Wolfgang Molzer, Ottobrunn (DE); Klaus Herold, Munich (DE); Joachim Singer, Munich (DE); Michael Langenbuch, Munich (DE); Thomas Wagner, Regelsbach (DE)

(73) Assignee: Intel Corporation, Santa Clara, CA (US)

(21) Appl. No.: 17/557,134

(22) Filed: Dec. 21, 2021

(51) Int. Cl. H01L 23/528; H01L 23/64; H01L 23/522

(52) U.S. Cl. CPC H01L 23/5286; H01L 23/645; H01L 23/5226

(57) ABSTRACT

IC devices including transformers that includes two electrically conductive layers are disclosed. An example IC device includes a transformer that includes a first coil, a second coil, and a magnetic core coupled to the two coils. The first coil includes a portion or the whole electrically conductive layers at the backside of a support structure. The second coil includes a portion or the whole electrically conductive layers at either the frontside or the backside of the support structure. The two coils may have a lateral coupling, vertical coupling, or other types of couplings. The transformer is coupled to a semiconductor device over or at least partially in the support structure. The semiconductor device may be at the frontside of the support structure. The transformer can be coupled to the semiconductor device by TSVs. The IC device may also include BPRs that facilitate backside power delivery to the semiconductor device.

### TECHNICAL FIELD

This disclosure relates generally to the field of semiconductor devices, and more specifically, to integrated circuit (IC) structures.

### BACKGROUND

For the past several decades, the scaling of features in ICs has been a driving force behind an ever-growing semiconductor industry. Scaling to smaller and smaller features enables increased densities of functional units on the limited real estate of semiconductor chips. For example, shrinking transistor size allows for the incorporation of an increased number of memory or logic devices on a chip, lending to the fabrication of products with increased capacity. Buried power rails (BPRs) can be a key scaling booster for complementary metal-oxide-semiconductor (CMOS) extension, e.g., beyond the 5-nm node.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 is a perspective view of an example fin-based field-effect transistor (FET), or FinFET, according to some embodiments of the disclosure.

FIG. 2 is a perspective view of an example IC device including a transformer that includes a backside electrically conductive layer, according to some embodiments of the disclosure.

FIG. 3 illustrates an example transformer formed by a lateral coupling between two coils, according to some embodiments of the disclosure.

FIG. 4 illustrates an example transformer formed by a vertical coupling between two coils, according to some embodiments of the disclosure.

FIG. 5A is a cross-sectional view of an example IC device including a transformer that includes two electrically conductive layers, according to some embodiments of the disclosure.

FIG. 5B is a top view of the example IC device in FIG. 5A, according to some embodiments of the disclosure.

FIG. 6A is a cross-sectional view of another example IC device including a transformer that includes two electrically conductive layers, according to some embodiments of the disclosure.

FIG. 6B is a top view of the example IC device in FIG. 6A, according to some embodiments of the disclosure.

FIG. 7 illustrates another example transformer that includes two electrically conductive layers, according to some embodiments of the disclosure.

FIGS. 8A-8H illustrate a process of forming an inductor at a backside of a support structure, according to some embodiments of the disclosure.

FIG. 9 is a cross-sectional view of an example IC device formed by the process in FIGS. 8A-H, according to some embodiments of the disclosure.

FIG. 10 is a cross-sectional view of another example IC device formed by the process in FIGS. 8A-H, according to some embodiments of the disclosure.

FIGS. 11A-11B are top views of a wafer and dies that may include one or more transformers that includes two electrically conductive layers, according to some embodiments of the disclosure.

FIG. 12 is a side, cross-sectional view of an example IC package that may include one or more IC devices having transformers that includes two electrically conductive layers, according to some embodiments of the disclosure.

FIG. 13 is a cross-sectional side view of an IC device assembly that may include components having one or more IC devices implementing transformers that includes two electrically conductive layers, according to some embodiments of the disclosure.

FIG. 14 is a block diagram of an example computing device that may include one or more components with transformers that includes two electrically conductive layers, according to some embodiments of the disclosure.

### DETAILED DESCRIPTION

Overview

The systems, methods, and devices of this disclosure each have several innovative aspects, no single one of which is solely responsible for all of the desirable attributes disclosed herein. Details of one or more implementations of the subject matter described in this specification are set forth in the description below and the accompanying drawings.

For purposes of illustrating IC devices with transformers that includes two electrically conductive layers, proposed herein, it might be useful to first understand phenomena that may come into play in such structures. The following foundational information may be viewed as a basis from which the present disclosure may be properly explained. Such information is offered for purposes of explanation only and, accordingly, should not be construed in any way to limit the broad scope of the present disclosure and its potential applications. While some of the following descriptions may be provided for the example of transistors being implemented as FinFETs, nanoribbon FETs, or nanowire FETs, embodiments of the present disclosure are equally applicable to IC devices employing transistors of other architectures such as to planar transistors.

Relentless scaling of transistors and wires in advanced semiconductor technologies has not only resulted in major process-related challenges but has also imposed severe design challenges in the sub-5 nm technology regime. Dimensional scaling of designs has been made possible by (i) Front-End-of-Line (FEOL) and Back-End-of-Line (BEOL) pitch scaling, which worsens short-channel effects in transistors and increases wire/contact resistances; and, (ii) fin depopulation in logic cells, which causes degradation of transistor drive. To enable further area scaling in sub-5 nm nodes, an approach of burying the power rails into the substrate has been proposed, which no longer requires reserving two routing tracks for power nets (e.g., VDD or VSS) in the logic cell area. Additionally, these BPRs can achieve a higher aspect ratio, thus, exhibiting lower resistance than local level BEOL power rails. BPRs can be a key scaling booster for complementary metal-oxide-semiconductor (CMOS) extension beyond the 5-nm node. Power lines which conventionally run outside substrates can be replaced with power lines “buried” within substrates, such as shallow trench isolation (STI) and Si substrate. Such power lines are called BPRs. A BPR is a power rail that is at least partially buried in a support structure, e.g., a substrate, die, etc. A BPR includes an electrically conductive material, such as metal. A rail can have an elongated structure having a longitudinal axis, which may be parallel to the frontside surface or the backside surface of the support structure. BPR frees up routing resources, which results in logic cell height reduction and overall area scaling.

Transformer devices are used for power delivery, impedance matching in RF applications and signal isolation. The performance of on-chip transformers is limited by the conductivity of thin metal lines, substrate losses, and small dimensions. Transformer devices are currently placed on the top metal layers and reserve a significant portion of the die area. No other device or signal/power routing can be added in the area where a transformer device has been placed. This leads to an increased die size which is a significant cost adder for advanced technology nodes. Thus, improved technology for forming transformers in CMOS structures is needed.

Embodiments of the present invention relate to IC devices including transformers that includes two electrically conductive layers. An example IC device includes one or more semiconductor devices, a support structure, a first and second BPRs, and a transformer. A semiconductor device may be a transistor, antenna, circuitry, or other types of semiconductor devices. The semiconductor device is at the frontside of the support structure. At least one of the two electrically conductive layers are at the backside of the support structure. The electrically conductive layers may have various couplings to form the transformer. In one embodiment, an electrically conductive layer includes two coils of the transformer, where the two coils have a lateral coupling. In another embodiment, a coil is in a first electrically conductive layer. Another coil is in a second electrically conductive layer that is over the first electrically conductive layer to form a vertical coupling. The two electrically conductive layers may be in parallel. In yet another embodiment, a coil included a portion of the first electrically conductive layer and a portion of the second electrically conductive layer, and the other coil includes another portion of the first electrically conductive layer and another portion of the second electrically conductive layer.

In some embodiments, a transformer can be formed in a structure (e.g., one or more redistribution layers) at the backside of the support structure. The IC device also includes transistors, a support structure, a first and second BPRs, and through-substrate vias (TSVs). A TSV may be at least partially in the support structure and may have a longitudinal axis perpendicular to the first surface or second surface. A TSV can extend from the frontside surface of the support structure to the backside surface of the support structure. The BPRs are coupled to the semiconductor device to deliver power to the semiconductor device. The TSVs includes a first TSV connected to a first coil of the transformer, a second TSV connected to the second coil of the transformer, a third TSV connected to the first BPR, and a fourth TSV connected to the second BPR. The structure can also include a power plane and a ground plane coupled to the two power rails, respectively, by the third and fourth TSVs. The power or ground plane is an electrically conductive layer, i.e., a layer including an electrically conductive material. The structure can also include an electrical insulator to insulate the power plane, ground plane, and electrical conductors of the transformer from each other.

The performance of transformers is increased by utilizing the BPR technology. The improved performance includes, for example, Q-factor of electrical conductors, coupling factor, and substrate loss. The BPR adds low ohmic conductors with good lateral alignment to the support structure. The design rules are compatible with CMOS metal lines. Different transformer types (such as electrical conductor structure including BPR and CMOS metal layers) can be used to optimize performance and to offer different electrical features. Also, transformers can also be used to couple BPRs with CMOS metal layers without using TSV, resulting in superior performance, e.g., by the option to skip ESD protection.

Elongated structures are mentioned throughout the present description. As used herein, a structure is referred to as an elongated if a length of the structure (measured alone one axis of an example coordinate system) is greater than both a width of the structure (measured along another axis of the example coordinate system) and a height of the structure (measured along a third axis of the example coordinate system). For example, elongated semiconductor structures as described herein may be fins or nanoribbons, having a length measured along an x-axis of the coordinate system shown in the present drawings, a width measured along a y-axis of the coordinate system shown in the present drawings, and a height measured along a z-axis of the coordinate system shown in the present drawings. Because BPRs described herein, as well as openings above them, are substantially parallel to the semiconductor structures, their lengths, widths, and heights are also measured along, respectively, an x-axis, a y-axis, and a z-axis of the x-y-z coordinate system shown in the present drawings. On the other hand, when the metal gate lines are substantially perpendicular to the semiconductor structures, as shown in the embodiments of the present drawings, their lengths, widths, and heights are measured along, respectively, a y-axis, an x-axis, and a z-axis of the x-y-z coordinate system shown.

While some of the descriptions provided herein refer to FinFETs, these descriptions are equally applicable to embodiments any other non-planar FETs besides FinFETs, e.g., to nanoribbon transistors, nanowire transistors, or transistors such as nanoribbon/nanowire transistors but having transverse cross-sections of any geometry (e.g., oval, or a polygon with rounded corners).

IC devices as described herein, in particular IC devices with including a transmission line placed based on BPRs as described herein, may be used for providing electrical connectivity to one or more components associated with an IC or/and between various such components. In various embodiments, components associated with an IC include, for example, transistors, diodes, power sources, resistors, capacitors, inductors, sensors, transceivers, receivers, antennas, etc. Components associated with an IC may include those that are mounted on IC or those connected to an IC. The IC may be either analog or digital and may be used in a number of applications, such as microprocessors, optoelectronics, logic blocks, audio amplifiers, etc., depending on the components associated with the IC. The IC may be employed as part of a chipset for executing one or more related functions in a computer.

For purposes of explanation, specific numbers, materials, and configurations are set forth in order to provide a thorough understanding of the illustrative implementations. However, it will be apparent to one skilled in the art that the present disclosure may be practiced without the specific details or/and that the present disclosure may be practiced with only some of the described aspects. In other instances, well-known features are omitted or simplified in order not to obscure the illustrative implementations.

Further, references are made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense. For convenience, if a collection of drawings designated with different letters are present, such a collection may be referred to herein without the letters.

In the drawings, some schematic illustrations of example structures of various devices and assemblies described herein may be shown with precise right angles and straight lines, this is simply for ease of illustration, and embodiments of these assemblies may be curved, rounded, or otherwise irregularly shaped as dictated by, and sometimes inevitable due to, the manufacturing processes used to fabricate semiconductor device assemblies. Therefore, it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication. Furthermore, although a certain number of a given element may be illustrated in some of the drawings (e.g., a certain number of semiconductor structures, a certain number of electrically conductive layers, a certain number of BPRs, a certain number of vias, a certain number of TSVs, a certain number of transmission lines, etc.), this is simply for ease of illustration, and more, or less, than that number may be included in an IC device with at least one BPR as described herein. Still further, various views shown in some of the drawings are intended to show relative arrangements of various elements therein. In other embodiments, various IC devices with BPRs as described herein, or portions thereof, may include other elements or components that are not illustrated (e.g., transistor portions, various components that may be in electrical contact with any of the transistors, etc.). Inspection of layout and mask data and reverse engineering of parts of a device to reconstruct the circuit using e.g., optical microscopy, TEM, or SEM, and/or inspection of a cross-section of a device to detect the shape and the location of various device elements described herein using e.g., Physical Failure Analysis (PFA) would allow determination of presence of IC devices with BPRs as described herein.

Various operations may be described as multiple discrete actions or operations in turn, in a manner that is most helpful in understanding the claimed subject matter. However, the order of description should not be construed as to imply that these operations are necessarily order dependent. These operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges.

The description uses the phrases “in an embodiment” or “in embodiments,” which may each refer to one or more of the same or different embodiments. The terms “comprising,” “including,” “having,” and the like, as used with respect to embodiments of the present disclosure, are synonymous. The disclosure may use perspective-based descriptions such as “above,” “below,” “top,” “bottom,” and “side” to explain various features of the drawings, but these terms are simply for ease of discussion, and do not imply a desired or required orientation. The accompanying drawings are not necessarily drawn to scale. Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner.

In the following detailed description, various aspects of the illustrative implementations will be described using terms commonly employed by those skilled in the art to convey the substance of their work to others skilled in the art.

For example, some descriptions may refer to a particular source or drain region or contact being either a source region/contact or a drain region/contact. However, unless specified otherwise, which region/contact of a transistor is considered to be a source region/contact and which region/contact is considered to be a drain region/contact is not important because under certain operating conditions, designations of source and drain are often interchangeable. Therefore, descriptions provided herein may use the term of a “S/D” region/contact to indicate that the region/contact can be either a source region/contact, or a drain region/contact.

In another example, if used, the terms “package” and “IC package” are synonymous, as are the terms “die” and “IC die,” the term “insulating” means “electrically insulating,” the term “conducting” means “electrically conducting,” unless otherwise specified. Although certain elements may be referred to in the singular herein, such elements may include multiple sub-elements. For example, “an electrically conductive material” may include one or more electrically conductive materials.

In another example, if used, the terms “oxide,” “carbide,” “nitride,” etc. refer to compounds containing, respectively, oxygen, carbon, nitrogen, etc., the term “high-k dielectric” refers to a material having a higher dielectric constant than silicon oxide, while the term “low-k dielectric” refers to a material having a lower dielectric constant than silicon oxide.

In yet another example, a term “interconnect” may be used to describe any element formed of an electrically conductive material for providing electrical connectivity to one or more components associated with an IC or/and between various such components. In general, the “interconnect” may refer to both conductive lines/wires (also sometimes referred to as “lines” or “metal lines” or “trenches”) and conductive vias (also sometimes referred to as “vias” or “metal vias”). In general, a term “conductive line” may be used to describe an electrically conductive element isolated by a dielectric material typically comprising an interlayer low-k dielectric that is provided within the plane of an IC chip. Such conductive lines are typically arranged in several levels, or several layers, of metallization stacks. On the other hand, the term “conductive via” may be used to describe an electrically conductive element that interconnects two or more conductive lines of different levels of a metallization stack. To that end, a via may be provided substantially perpendicularly to the plane of an IC chip or a support structure over which an IC device is provided and may interconnect two conductive lines in adjacent levels or two conductive lines in not adjacent levels. A term “metallization stack” may be used to refer to a stack of one or more interconnects for providing connectivity to different circuit components of an IC chip.

Furthermore, the term “connected” may be used to describe a direct electrical or magnetic connection between the things that are connected, without any intermediary devices, while the term “coupled” may be used to describe either a direct electrical or magnetic connection between the things that are connected, or an indirect connection through one or more passive or active intermediary devices. The term “circuit” may be used to describe one or more passive and/or active components that are arranged to cooperate with one another to provide a desired function.

The terms “substantially,” “close,” “approximately,” “near,” and “about,” generally refer to being within +/−20% of a target value based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−5-20% of a target value based on the context of a particular value as described herein or as known in the art.

Example FinFET

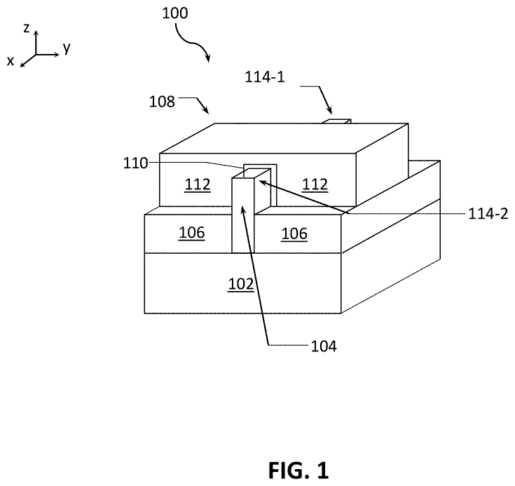

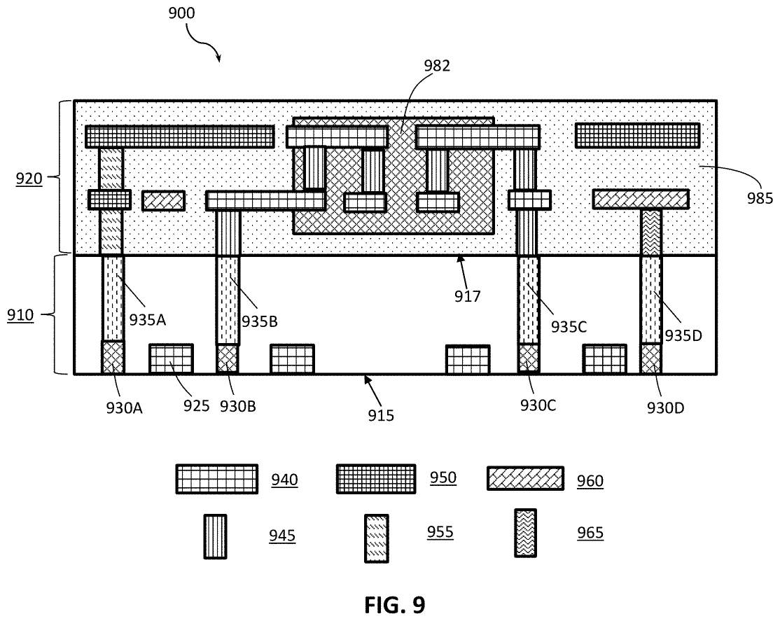

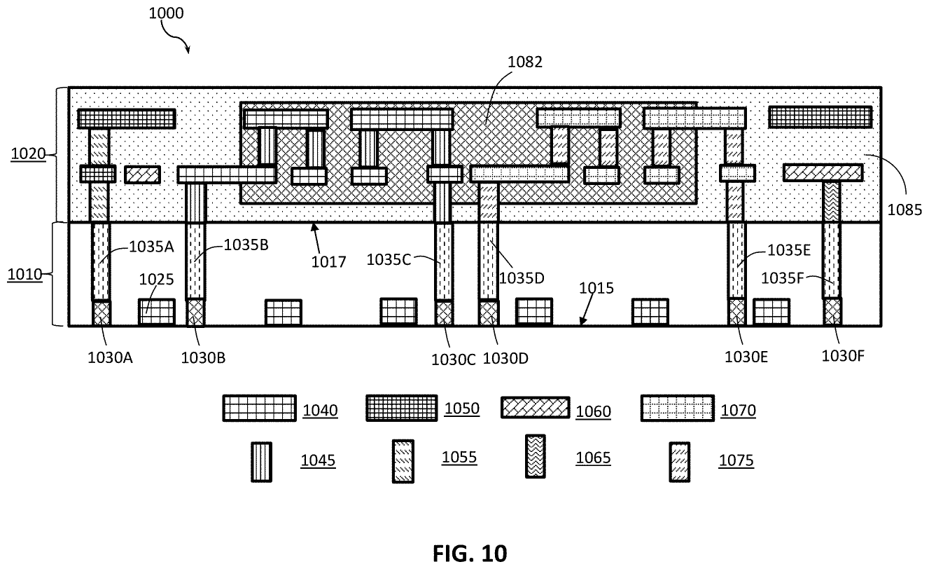

FIG. 1 is a perspective view of an example FinFET 100, according to some embodiments of the disclosure. The FinFET 100 illustrates one example of a transistor over or at least partially in a support structure. For example, the FinFET 100 may be a transistor illustrated in the IC devices shown in FIGS. 9-10. The FinFET 100 shown in FIG. 1 is intended to show relative arrangement(s) of some of the components therein. In various embodiments, the FinFET 100, or portions thereof, may include other components that are not illustrated (e.g., any further materials, such as spacer materials, surrounding the gate stack of the FinFET 100, electrical contacts to the S/D regions of the FinFET 100, etc.).

As shown in FIG. 1, the FinFET 100 may be provided over a support structure 102, where the support structure 102 may be any suitable support structure on which a transistor may be built, e.g., a substrate, a die, a wafer, or a chip. As also shown in FIG. 1, the FinFET 100 may include a fin 104, extending away from the support structure 102. A portion of the fin 104 that is closest to the support structure 102 may be enclosed by an insulator material 106, commonly referred to as an “STI material” or, simply, “STI.” The portion of the fin 104 enclosed on its' sides by the STI 106 is typically referred to as a “subfin portion” or simply a “subfin.” As further shown in FIG. 1, a gate stack 108 that includes at least a layer of a gate electrode material 112 and, optionally, a layer of a gate dielectric 110, may be provided over the top and sides of the remaining upper portion of the fin 104 (e.g., the portion above and not enclosed by the STI 106), thus wrapping around the upper-most portion of the fin 104. The portion of the fin 104 over which the gate stack 108 wraps around may be referred to as a “channel portion” of the fin 104 because this is where, during operation of the FinFET 100, a conductive channel may form. The channel portion of the fin 104 is a part of an active region of the fin 104. A first S/D region 114-1 and a second S/D region 114-2 (also commonly referred to as “diffusion regions”) are provided on the opposite sides of the gate stack 108, forming source and drain terminals of the FinFET 100.

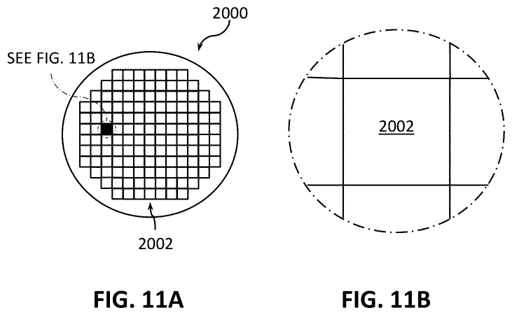

In general, implementations of the present disclosure may be formed or carried out on a support structure such as a semiconductor substrate, composed of semiconductor material systems including, for example, n-type or p-type materials systems. In one implementation, the semiconductor substrate may be a crystalline substrate formed using a bulk silicon or a silicon-on-insulator substructure. In other implementations, the semiconductor substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-V, group II-VI, or group IV materials. In some embodiments, the substrate may be non-crystalline. In some embodiments, the support structure 102 may be a printed circuit board (PCB) substrate. Although a few examples of materials from which the substrate may be formed are described here, any material that may serve as a foundation upon which transformers as described herein may be built falls within the spirit and scope of the present disclosure. In various embodiments, the support structure 102 may include any such substrate material that provides a suitable surface for forming the FinFET 100. The support structure 102 may, e.g., be the wafer 2000 of FIG. 11A, discussed below, and may be, or be included in, a die, e.g., the singulated die 2002 of FIG. 11B, discussed below.

As shown in FIG. 1, the fin 104 may extend away from the support structure 102 and may be substantially perpendicular to the support structure 102. The fin 104 may include one or more semiconductor materials, e.g., a stack of semiconductor materials, so that the upper-most portion of the fin (namely, the portion of the fin 104 enclosed by the gate stack 108) may serve as the channel region of the FinFET 100. Therefore, as used herein, the term “channel material” of a transistor may refer to such upper-most portion of the fin 104, or, more generally, to any portion of one or more semiconductor materials in which a conductive channel between source and drain regions may be formed during operation of a transistor.

As shown in FIG. 1, the STI material 106 may enclose the sides of the fin 104. A portion of the fin 104 enclosed by the STI 106 forms a subfin. In various embodiments, the STI material 106 may be a low-k or high-k dielectric including, but not limited to, elements such as hafnium, silicon, oxygen, nitrogen, titanium, tantalum, lanthanum, aluminum, zirconium, barium, strontium, yttrium, lead, scandium, niobium, and zinc. Further examples of dielectric materials that may be used in the STI material 106 may include, but are not limited to silicon nitride, silicon oxide, silicon dioxide, silicon carbide, silicon nitride doped with carbon, silicon oxynitride, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate.

Above the subfin portion of the fin 104, the gate stack 108 may wrap around the fin 104 as shown in FIG. 1. In particular, the gate dielectric 110 may wrap around the upper-most portion of the fin 104, and the gate electrode 112 may wrap around the gate dielectric 110. The interface between the channel portion of the fin 104 and the subfin portion of the fin 104 is located proximate to where the gate electrode 112 ends.

The gate electrode 112 may include one or more gate electrode materials, where the choice of the gate electrode materials may depend on whether the FinFET 100 is a p-type metal-oxide-semiconductor (PMOS) transistor or an n-type metal-oxide-semiconductor (NMOS) transistor. For a PMOS transistor, gate electrode materials that may be used in different portions of the gate electrode 112 may include, but are not limited to, ruthenium, palladium, platinum, cobalt, nickel, and conductive metal oxides (e.g., ruthenium oxide). For an NMOS transistor, gate electrode materials that may be used in different portions of the gate electrode 112 include, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide). In some embodiments, the gate electrode 112 may include a stack of a plurality of gate electrode materials, where zero or more materials of the stack are workfunction (WF) materials and at least one material of the stack is a fill metal layer. Further materials/layers may be included next to the gate electrode 112 for other purposes, such as to act as a diffusion barrier layer or/and an adhesion layer.

If used, the gate dielectric 110 may include a stack of one or more gate dielectric materials. In some embodiments, the gate dielectric 110 may include one or more high-k dielectric materials. In various embodiments, the high-k dielectric materials of the gate dielectric 110 may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric 110 may include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate. In some embodiments, an annealing process may be carried out on the gate dielectric 110 during manufacture of the FinFET 100 to improve the quality of the gate dielectric 110.

In some embodiments, the gate stack 108 may be surrounded by a dielectric spacer, not specifically shown in FIG. 1. The dielectric spacer may be configured to provide separation between the gate stacks 108 of different FinFETs 100 which may be provided along a single fin (e.g., different FinFETs provided along the fin 104, although FIG. 1 only illustrates one of such FinFETs), as well as between the gate stack 108 and the source/drain contacts disposed on each side of the gate stack 108. Such a dielectric spacer may include one or more low-k dielectric materials. Examples of the low-k dielectric materials that may be used as the dielectric spacer include, but are not limited to, silicon dioxide, carbon-doped oxide, silicon nitride, fused silica glass (FSG), and organosilicates such as silsesquioxane, siloxane, and organosilicate glass. Other examples of low-k dielectric materials that may be used as the dielectric spacer include organic polymers such as polyimide, polynorbornenes, benzocyclobutene, perfluorocyclobutane, or polytetrafluoroethylene (PTFE). Still other examples of low-k dielectric materials that may be used as the dielectric spacer include silicon-based polymeric dielectrics such as hydrogen silsesquioxane (HSQ) and methylsilsesquioxane (MSQ). Other examples of low-k materials that may be used in a dielectric spacer include various porous dielectric materials, such as for example porous silicon dioxide or porous carbon-doped silicon dioxide, where large voids or pores are created in a dielectric in order to reduce the overall dielectric constant of the layer, since voids can have a dielectric constant of nearly 1. When such a dielectric spacer is used, then the lower portions of the fin 104, e.g., the subfin portion of the fin 104, may be surrounded by the STI material 106 which may, e.g., include any of the high-k dielectric materials described herein.

In some embodiments, the fin 104 may be composed of semiconductor material systems including, for example, n-type or p-type materials systems. In some embodiments, the fin 104 may include a high mobility oxide semiconductor material, such as tin oxide, antimony oxide, indium oxide, indium tin oxide, titanium oxide, zinc oxide, indium zinc oxide, gallium oxide, titanium oxynitride, ruthenium oxide, or tungsten oxide. In some embodiments, the fin 104 may include a combination of semiconductor materials where one semiconductor material is used for the channel portion and another material, sometimes referred to as a “blocking material,” is used for at least a portion of the subfin portion of the fin 104. In some embodiments, the subfin and the channel portions of the fin 104 are each formed of monocrystalline semiconductors, such as silicon or germanium. In a first embodiment, the subfin and the channel portion of the fin 104 are each formed of compound semiconductors with a first sub-lattice of at least one element from group III of the periodic table (e.g., Al, Ga, In), and a second sub-lattice of at least one element of group V of the periodic table (e.g., P, As, Sb). The subfin may be a binary, ternary, or quaternary III-V compound semiconductor that is an alloy of two, three, or even four elements from groups III and V of the periodic table, including boron, aluminum, indium, gallium, nitrogen, arsenic, phosphorus, antimony, and bismuth.

For some example n-type transistor embodiments (i.e., for the embodiments where the FinFET 100 is an NMOS), the channel portion of the fin 104 may advantageously include a III-V material having a high electron mobility, such as, but not limited to InGaAs, InP, InSb, and InAs. For some such embodiments, the channel portion of the fin 104 may be a ternary III-V alloy, such as InGaAs, GaAsSb, InAsP, or InPSb. For some InₓGa₁₋ₓAs fin embodiments, In content (x) may be between 0.6 and 0.9, and may advantageously be at least 0.7 (e.g., In_{0.7}Ga_{0.3}As). In some embodiments with highest mobility, the channel portion of the fin 104 may be an intrinsic III-V material, i.e., a III-V semiconductor material not intentionally doped with any electrically active impurity. In alternate embodiments, a nominal impurity dopant level may be present within the channel portion of the fin 104, for example to further fine-tune a threshold voltage Vt, or to provide HALO pocket implants, etc. Even for impurity-doped embodiments however, impurity dopant level within the channel portion of the fin 104 may be relatively low, for example below 10¹⁵ dopant atoms per cubic centimeter (cm⁻³), and advantageously below 10¹³ cm⁻³. The subfin portion of the fin 104 may be a III-V material having a band offset (e.g., conduction band offset for n-type devices) from the channel portion. Example materials include, but are not limited to, GaAs, GaSb, GaAsSb, GaP, InAlAs, GaAsSb, AlAs, AlP, AlSb, and AlGaAs. In some n-type transistor embodiments of the FinFET 100 where the channel portion of the fin 104 is InGaAs, the subfin may be GaAs, and at least a portion of the subfin may also be doped with impurities (e.g., p-type) to a greater impurity level than the channel portion. In an alternate heterojunction embodiment, the subfin and the channel portion of the fin 104 are each, or include, group IV semiconductors (e.g., Si, Ge, SiGe). The subfin of the fin 104 may be a first elemental semiconductor (e.g., Si or Ge) or a first SiGe alloy (e.g., having a wide bandgap).

For some example p-type transistor embodiments (i.e., for the embodiments where the FinFET 100 is a PMOS), the channel portion of the fin 104 may advantageously be a group IV material having a high hole mobility, such as, but not limited to Ge or a Ge-rich SiGe alloy. For some example embodiments, the channel portion of the fin 104 may have a Ge content between 0.6 and 0.9, and advantageously may be at least 0.7. In some embodiments with highest mobility, the channel portion may be intrinsic III-V (or IV for p-type devices) material and not intentionally doped with any electrically active impurity. In alternate embodiments, one or more a nominal impurity dopant level may be present within the channel portion of the fin 104, for example to further set a threshold voltage Vt, or to provide HALO pocket implants, etc. Even for impurity-doped embodiments however, impurity dopant level within the channel portion is relatively low, for example below 10¹⁵ cm⁻³, and advantageously below 10¹³ cm⁻³. The subfin of the fin 104 may be a group IV material having a band offset (e.g., valance band offset for p-type devices) from the channel portion. Example materials include, but are not limited to, Si or Si-rich SiGe. In some p-type transistor embodiments, the subfin of the fin 104 is Si and at least a portion of the subfin may also be doped with impurities (e.g., n-type) to a higher impurity level than the channel portion.

Turning to the first S/D region 114-1 and the second S/D region 114-2 on respective different sides of the gate stack 108, in some embodiments, the first S/D region 114-1 may be a source region and the second S/D region 114-2 may be a drain region. In other embodiments this designation of source and drain may be interchanged, i.e., the first S/D region 114-1 may be a drain region and the second S/D region 114-2 may be a source region. Although not specifically shown in FIG. 1, the FinFET 100 may further include S/D electrodes (also commonly referred to as “S/D contacts”), formed of one or more electrically conductive materials, for providing electrical connectivity to the S/D regions 114, respectively. In some embodiments, the S/D regions 114 of the FinFET 100 may be regions of doped semiconductors, e.g., regions of doped channel material of the fin 104, so as to supply charge carriers for the transistor channel. In some embodiments, the S/D regions 114 may be highly doped, e.g., with dopant concentrations of about 1·10²¹ cm⁻³, in order to advantageously form Ohmic contacts with the respective S/D electrodes, although these regions may also have lower dopant concentrations and may form Schottky contacts in some implementations. Irrespective of the exact doping levels, the S/D regions 114 of the FinFET 100 are the regions having dopant concentration higher than in other regions, e.g., higher than a dopant concentration in a region of the semiconductor channel material between the first S/D region 114-1 and the second S/D region 114-2, and, therefore, may be referred to as “highly doped” (HD) regions.

In some embodiments, the S/D regions 114 may generally be formed using either an implantation/diffusion process or an etching/deposition process. In the former process, dopants such as boron, aluminum, antimony, phosphorous, or arsenic may be ion-implanted into the one or more semiconductor materials of the upper portion of the fin 104 to form the S/D regions 114. An annealing process that activates the dopants and causes them to diffuse further into the fin 104 may follow the ion implantation process. In the latter process, the one or more semiconductor materials of the fin 104 may first be etched to form recesses at the locations for the future source and drain regions. An epitaxial deposition process may then be carried out to fill the recesses with material (which may include a combination of different materials) that is used to fabricate the S/D regions 114. In some implementations, the S/D regions 114 may be fabricated using a silicon alloy such as silicon germanium or silicon carbide. In some implementations, the epitaxially deposited silicon alloy may be doped in situ with dopants such as boron, arsenic, or phosphorous. In further embodiments, the S/D regions 114 may be formed using one or more alternate semiconductor materials such as germanium or a group III-V material or alloy. Although not specifically shown in the perspective illustration of FIG. 1, in further embodiments, one or more layers of metal and/or metal alloys may be used to form the source and drain contacts (i.e., electrical contacts to each of the S/D regions 114).

The FinFET 100 may have a gate length, GL, (i.e., a distance between the first S/D region 114-1 and the second S/D region 114-2), a dimension measured along the longitudinal axis of the fin 104, which extends in the direction of the x-axis of the example reference coordinate system x-y-z shown in the present drawings, where the gate length may, in some embodiments, be between about 5 and 40 nanometers, including all values and ranges therein (e.g. between about 22 and 35 nanometers, or between about 15 and 25 nanometers). The fin 104 may have a thickness, a dimension measured in the direction of the y-axis of the reference coordinate system x-y-z shown in FIG. 1, that may, in some embodiments, be between about 4 and 15 nanometers, including all values and ranges therein (e.g., between about 5 and 10 nanometers, or between about 7 and 12 nanometers). The fin 104 may have a height, a dimension measured in the direction of the z-axis of the reference coordinate system x-y-z shown in FIG. 1, which may, in some embodiments, be between about 30 and 350 nanometers, including all values and ranges therein (e.g., between about 30 and 200 nanometers, between about 75 and 250 nanometers, or between about 150 and 300 nanometers).

Although the fin 104 is illustrated in FIG. 1 as having a rectangular cross-section in a z-y plane of the reference coordinate system shown in FIG. 1, the fin 104 may instead have a cross-section that is rounded or sloped at the “top” of the fin 104, and the gate stack 108 (including the different portions of the gate dielectric 110) may conform to this rounded or sloped fin 104. In use, the FinFET 100 may form conducting channels on three “sides” of the channel portion of the fin 104, potentially improving performance relative to single-gate transistors (which may form conducting channels on one “side” of a channel material or substrate) and double-gate transistors (which may form conducting channels on two “sides” of a channel material or substrate). While FIG. 1 illustrates a single FinFET 100, in some embodiments, a plurality of FinFETs may be arranged next to one another (with some spacing in between) along the fin 104.

Other types of semiconductor structures can be used in a FET. For example, nanoribbon-based FETs include elongated semiconductor structures called nanoribbons as semiconductor structures. As another example, nanowire-based FETs include nanowires as semiconductor structures. As used herein, the term “nanoribbon” refers to an elongated semiconductor structure having a longitudinal axis parallel to the support structure over which a memory device is provided. Typically, a length of a such a structure (i.e., a dimension measured along the longitudinal axis, shown in the present drawings to be along the y-axis of an example x-y-z coordinate system) is greater than each of a width (i.e., a dimension measured along the x-axis of the example coordinate system shown in the present drawings) and a thickness/height (i.e., a dimension measured along the z-axis of the example coordinate system shown in the present drawings). In some settings, the terms “nanoribbon” or “nanosheet” have been used to describe elongated semiconductor structures that have a rectangular transverse cross-section (i.e., a cross-section in a plane perpendicular to the longitudinal axis of the structure), while the term “nanowire” has been used to describe similar elongated structures but with circular transverse cross-sections.

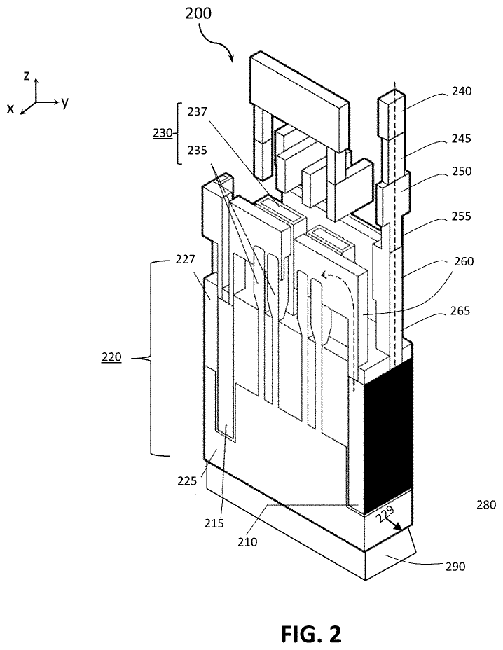

FIG. 2 is a perspective view of an example IC device 200 including a transformer that includes a backside electrically conductive layer 290, according to some embodiments of the disclosure. The IC device 200 also includes another BPR 215, a support structure 220 where the BPRs 210 and 215 are buried, transistors 230 (individually referred to as “transistor 230”), electrically conductive layers 240, 250, and 260, and vias 245, 255, and 265. In other embodiments, the IC device 200 may include more, fewer, or different components. In some embodiments, the components of the IC device 200 may be arranged differently. For instance, the electrically conductive layer 240 may be arranged below the support structure 220 for backside power delivery.

A transistor 230 includes semiconductor structures 235 (individually referred to as “semiconductor structure 235”) and a gate 237. A semiconductor structure 235 may be a fin, nanoribbon, or nanowire of a semiconductor material. In some embodiments, at least a portion of a semiconductor structure 235 are formed in the support structure 220. The gate 237 has a first portion at least partially wrapping around a portion of a semiconductor structure 235 on a source region of the transistor 230. The gate 237 also has a second portion at least partially wrapping around a portion of another semiconductor structure 235 on a drain region of the transistor 230. An embodiment of the gate 237 is the gate stack 108 in FIGS. 1-3. A transistor 230 may be a NMOS or PMOS transistor.

The support structure 220 includes a semiconductor layer 225 and an insulator layer 227. A portion of each BPR 210 or 215 is buried in the semiconductor layer 225, and the remaining portion of the BPR 210 or 215 is buried in the insulator layer 227. The semiconductor layer 225 includes a semiconductor material. Examples of the semiconductor material include, for example, single crystal silicon, polycrystalline silicon, silicon-on-insulator (SOI), other suitable semiconductor material, or some combination thereof. The semiconductor layer 225 may also include other materials, such as metal, dielectric, dopant, and so on. In FIG. 2, the semiconductor layer 225 has a top surface and a bottom surface. The top surface of the semiconductor layer 225 contacts with the bottom surface of the insulator layer 227. The bottom surface of the semiconductor layer 225 is the bottom surface of the IC device 200 and can be referred to as the backside of the IC device 200. In some embodiments, the semiconductor layer 225, or a portion of it, is dopped to generate a p-type support structure or n-type support structure.

The insulator layer 227 functions as an electrical insulator that isolates conducting and semiconducting materials from each other. In some embodiments, the insulator layer 227 is an oxide layer. An example oxide layer is a layer of silicon oxide, SiOₓ, where x is an integer number, such as 2, 2, etc. The insulator layer 227 adjoins the semiconductor layer 225. As shown in FIG. 2, the insulator layer 227 is above the semiconductor layer 225. In some embodiments, the insulator layer 227 is not a continuous insulator layer. Rather, the insulator layer 227 includes discrete insulator sections arranged in the semiconductor material of the semiconductor layer 225. The discrete insulator sections can insulate BPRs from the semiconductor material. The discrete insulator sections can also insulate semiconductor structures, which are formed in the semiconductor layer 225, of transistors from each other. The discrete insulator sections may include an oxide of the semiconductor material and can be formed from portions of the semiconductor layer 225.

In some embodiments, the insulator layer 227 may be formed by transforming a portion of a silicon support structure into silicon oxide. Silicon exposed to ambient conditions has a native oxide on its surface. The native oxide is approximately 3 nm thick at room temperature. However, 3 nm may be too thin for most applications and a thicker insulator layer needs to be grown. This is done by consuming the underlying Si to form SiOx. This is a grown layer. It is also possible to grow SiOx by a chemical vapor deposition process using Si and O precursor molecules. In this embodiment, the underlying Si in the wafer is not consumed. This is called a deposited layer. In some embodiments, the insulator layer 227 helps in protecting the components in the support structure 220 from contamination, both physical and chemical. Thus, it acts as a passivating layer. The insulator layer 227 can protect the components in the support structure 220 from scratches and it also prevents dust from interacting with the components in the support structure 220, and thus minimizes contamination. The insulator layer 227 also protects the components in the support structure 220 from chemical impurities, mainly electrically active contaminants. SiOx acts as a hard mask for doping and as an etch stop during patterning.

The BPRs 210 and 215 are electrically conductive. The BPRs 210 and 215 are coupled to one or more power sources and to semiconductor devices in the IC device 200 (such as the transistors 230) to provide power to the semiconductor devices. In FIG. 2, the two BPRs 210 and 215 are buried in the support structure 220. A portion of each BPR 210 or 215 is buried in the insulator layer 227. The remaining portion of each BPR 210 or 215 is buried in the semiconductor layer 225. The BPRs 210 and 215 may be made of a metal, such as tungsten (W), ruthenium (Ru), cobalt (Co), other metals, or some combination thereof. Each BPR 210 or 215 may include a dielectric barrier on its surface that touches the semiconductor layer 225. The dielectric barrier can insulate the metal in the BPR 210 or 215 from the semiconductor material of the semiconductor layer 225. The dielectric barrier may be an oxide barrier made from an oxide material.

The electrically conductive layers 240, 250, and 260 are built in the IC device 200 to provide power and signal to the semiconductor devices in the IC device 200. An electrically conductive layer is a layer comprising an electrically conductive material, e.g., metal. In an embodiment, the electrically conductive layers 240 and 260 are used for power delivery but the electrically conductive layer 250 is used for signal delivery. In some embodiments, the electrically conductive layer 260 is referred to as “MO,” the electrically conductive layer 250 is referred to as “Mint,” and the electrically conductive layer 260 is referred to as “Ml,” given the sequence of producing the electrically conductive layers 240, 250, and 260 in the process of fabricating the IC device 200. The electrically conductive layers 240, 250, and 260 can be made of copper or other types of metals. Each electrically conductive layer 240, 250, or 260 includes multiple sections that can be separated and insulated from each other.

The BPRs 210 and 215, electrically conductive layers 240, 250, and 260, and vias 245, 255, and 265 constitute a conducting path for power delivery network, as indicated by the dotted line in FIG. 2. The vias 245, 255, and 265 are conducting. In one embodiment, some or all of the vias 245, 255, and 265 are made of copper or other types of metal. The vias 245 are between the electrically conductive layers 240 and 250 to couple the two electrically conductive layers 240 and 250 to each other. As shown in FIG. 2, there are three vias 245 between the electrically conductive layers 240 and 250. Each via 245 is for coupling a section of the electrically conductive layer 240 to a corresponding section of the electrically conductive layer 250. In other embodiments, there can be fewer or more vias 245 to couple the electrically conductive layers 240 and 250. Similarly, the via 255 is between the electrically conductive layers 250 and 260. The vias 265 couple the BPRs 210 and 215 to the electrically conductive layer 260. In FIG. 2, there are two vias 265 connecting the BPR 210 to the electrically conductive layer 260 and two vias 265 connecting the BPR 215 to the electrically conductive layer 260. The electrically conductive layer 260 is coupled to the transistors 230, particularly to semiconductor structures 235 of the transistors 230.

In an example, the electrically conductive layer 240 functions as the power plane of the IC device 200. A positive or negative voltage, for example, can be provided to the electrically conductive layer 240 so that the BPR 210 is electrically biased. The BPR 215 is grounded so that there is an electric potential difference between the BPRs 210 and 215, which transfers to the electric potential difference between the transistors 230. As the electrically conductive layer 240 is on top of the transistors 230, the power delivery network is called “frontside power delivery network.” In other embodiments, the IC device 200 may include an electrically conductive layer below the transistors 230, e.g., at the backside of the IC device 200. The electrically conductive layer may function as the power plane, ground plane, or both to form “backside power delivery network”. The BPRs 210 and 215 can be coupled to the electrically conductive layer by TSVs. The TSVs are below the BPRs 210 and 215 and buried in the semiconductor layer 225 of the support structure 220. The TSVs may be micro-TSVs or nano-TSVs. The power delivery network of the IC device 200 can be a network of interconnect that is separate from the signal network. For instance, portions of the electrically conductive layer 250 that are not in the power delivery network can be used to deliver signals.

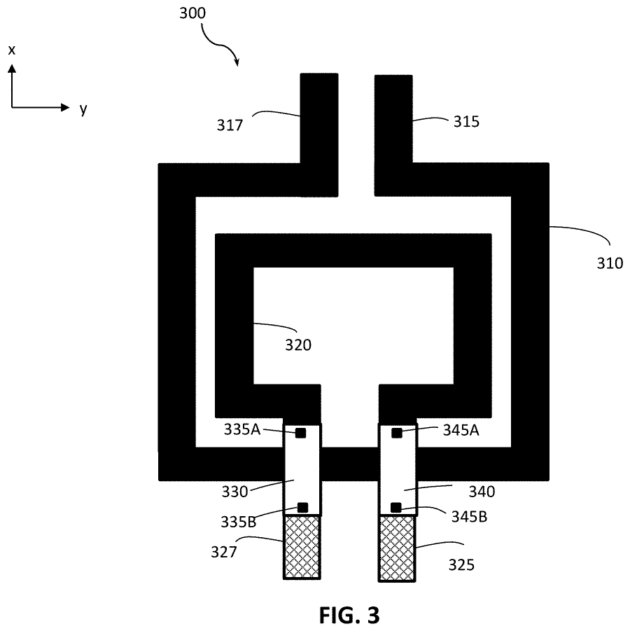

The transformer includes a first and second coils. The first coil includes the electrically conductive layer 260, which is at the frontside. The second coil includes the electrically conductive layer 290, which is at the backside. The two coils have a vertical coupling as they are arranged on different planes. In other embodiments, both coils are at the backside. The two coils may have a lateral coupling. For instance, the coils are arranged on a same plane. A coil may be enclosed by the other coil in the x-z plane. In More details regarding transformer that includes two electrically conductive layers are provided below in conjunction with FIGS. 3-7.

In some embodiments, the IC device 200 is fabricated through a sequence of processes. Well formation is done as the first step. The first step comprises, for example, ion implantation and dopant activation anneal. Alternatively, well formation can be done after the fin reveal step. Subsequently, fin patterning and insulator layer formation are carried out. The insulator layer formation step may include silicon oxide deposition, silicon oxide anneal, and chemical mechanical polishing (CMP). The BPRs 210 and 215 are formed in the next step, which includes patterning BPR trench into the support structure 220. Subsequently, a dielectric barrier may be deposited onto the outer surfaces of the BPRs 210 and 215 (i.e., the surfaces touching the support structure 220) to electrically isolate the BPRs 210 and 215 from the support structure 220. In some embodiments, the step of forming the BPRs 210 and 215 may further include metal CMP and silicon oxide anneal. Next, fin reveal is carried out, e.g., by etching, to reveal the fins. After that, the electrically conductive layers 240, 250, and 260 and vias 245, 255, and 265 are integrated into the IC device 200.

FIG. 3 illustrates a cross-sectional view of a transformer 300 formed by a lateral coupling between two coils 310 and 320, according to some embodiments of the disclosure. The coil 310 and coil 320 constitute the two electrical conductors of the transformer 300. Each coil includes an electrically conductive material, such as metal. The coils may include the same material or different materials.

With the lateral coupling, the coil 310 and the coil 320 do not overlap. Rather, the coil 320 has a smaller size than the coil 310. In the cross-sectional view in FIG. 3, the coil 310 encloses the coil 320. The lateral coupling between the coil 310 and coil 320 results in lower magnetic coupling (k-factor). When electrical currents flow through the coil 310 and coil 320, a vertical magnetic field, i.e., a magnetic field in a direction perpendicular to the x-y plane, is generated.

The coil 310 or 320 is a portion or whole of an electrically conductive layer in an IC device including a support structure, such as the support structure 220. The coil 310 or 320 may be at the frontside or backside of the support structure. In some embodiments, the coil 310 and 320 are in a same layer at the backside of the support structure. The layer, for example, is in the x-y plane. For instance, the coil 310 is a first electrically conductive structure of the layer, the coil 320 is a second electrically conductive structure of the layer. The two coils 310 and 320 can be separated and insulated by an electrical insulator in the layer. In some embodiments, the layer adjoins the backside surface of the support structure. In other embodiments, the coil 310 and 320 are in two different layers. The two layers are in parallel. For instance, the coil 310 is in the x-y plane, the coil 320 is in a plane that is parallel to the x-y plane. The two layers may be at opposite sides of the support structure or are both at the backside of the support structure. In the embodiment of FIG. 3, the coils 310 and 320 have rectangular ring shapes. In other embodiments, the coils 310 and 320 can have other shapes, e.g., square, octagonal, circle, and so on.

The coil 310 has two ends 315 and 317. In some embodiments, the coil 310 is coupled to one or more semiconductor devices (e.g., transistor, antenna, circuitry, or other types of semiconductor devices) through the ends 315 and 317. In one example, the end 315 is coupled to a signal plane and the end 317 is coupled to a ground plane. The coil 320 is associated with coupling structures 325 and 327. In embodiments where the coils 310 and 320 are in the same x-y plane, two crossing structures 330 and 340 are needed to couple the coil 320 to the coupling structures 325 and 327. A coupling structure or crossing structure may be a structure (e.g., an elongated structure) that includes an electrically conductive material. The elongate structure may have a longitudinal axis parallel to the corresponding layer.

The crossing structures 330 and 340 are over a portion of the coil 310 to couple the ends of the coil 320 to the coupling structures 325 and 327. For instance, the crossing structures 330 and 340 is in a first layer that is parallel to and over a second layer where the coils 310 and 320 are located. The coupling structures 325 and 327 are in the second layer. A portion of the coil 310 is between an end of the coil 320 and the corresponding coupling structure 325 or 327. In some embodiments, the first layer can be between a support structure and the second layer. The first and second layer are at the backside of the support structure. The crossing structure 330 is coupled to one end of the coil 320 by two vias 335A-B. Similarly, the crossing structure 340 is coupled to the other end of the coil 320 by two vias 345A-B. Each via crosses a portion of the first layer and a portion of the second layer. A via can have a longitudinal axis that is perpendicular to the layer of the coils 310 and 320. In some embodiments, the coil 320 is coupled to one or more semiconductor devices through the coupling structures 325 and 327. For instance, the coupling structure 325 is coupled to a signal plane, and the coupling structure 327 is coupled to a ground plane.

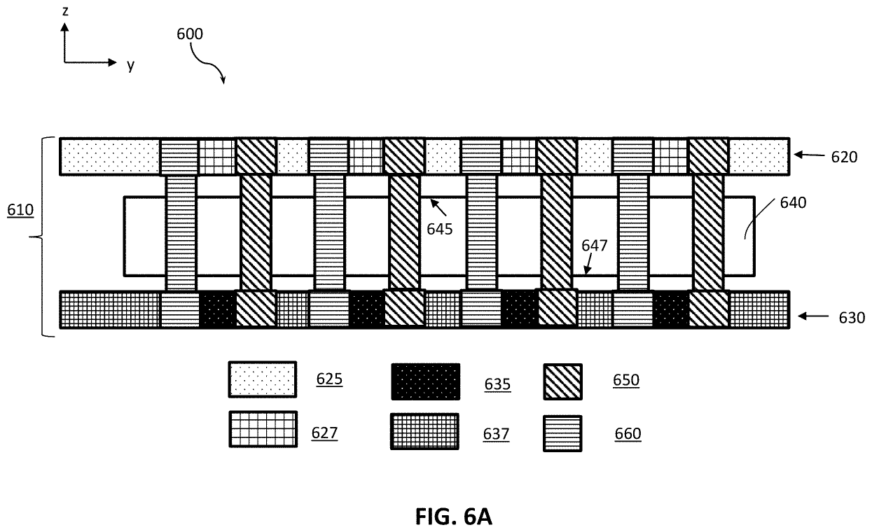

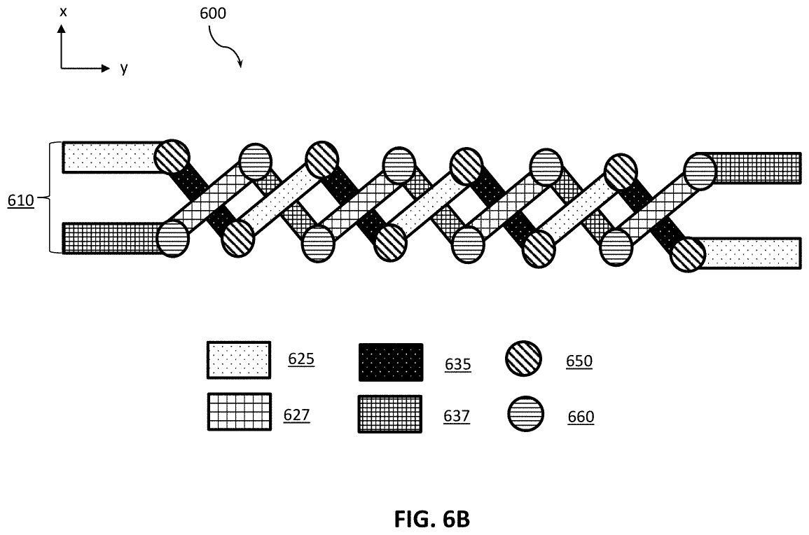

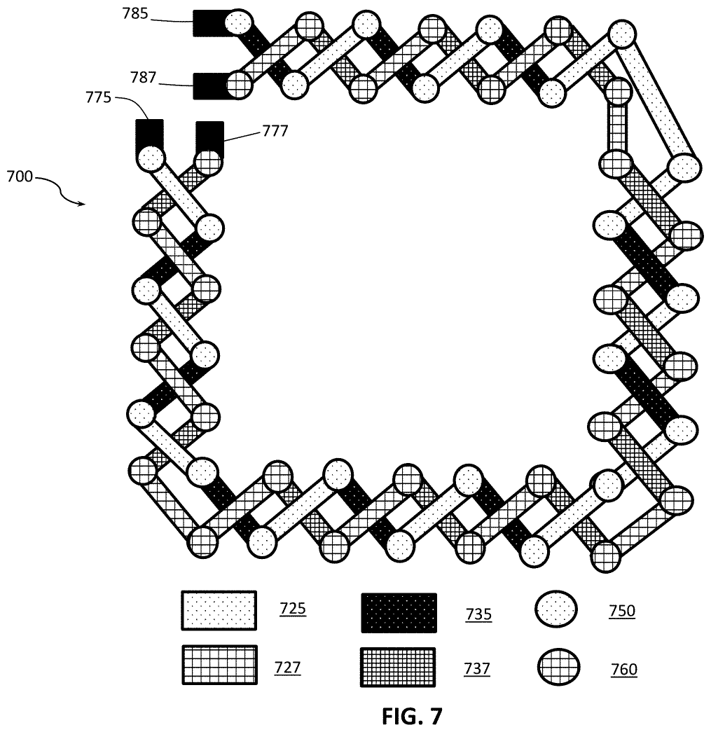

As shown in FIG. 3, the coil 310 and coil 320 are both round. In other embodiments, the coil 310 and coil 320 may have other shapes, such as squares, rectangles, octagonal (using 45° lines), or more complicated shapes (such as the shapes shown in FIGS. 6 and 7). Also, for purpose of illustration and simplicity, the transformer 300 in FIG. 3 has one primary winding and one secondary winding with a 1:1 turn ratio. In other embodiments, the transformer 300 may have a different turn ratio and different numbers of windings.

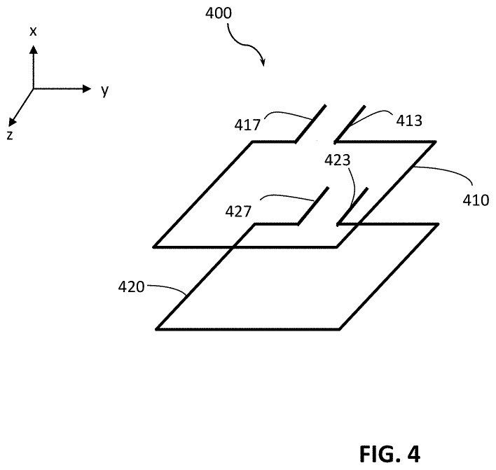

FIG. 4 illustrates an example transformer 400 formed by a vertical coupling between two coils 410 and 420, according to some embodiments of the disclosure. The coil 410 and coil 420 constitute the two electrical conductors of the transformer 400. When electrical currents flow through the coil 410 and coil 420, a vertical magnetic field is generated. In the embodiment of FIG. 4, the coil 410 is vertically coupled with the coil 420, i.e., the coil 410 is over the coil 420. With the vertical coupling between the coil 410 and coil 420, the transformer 400 can achieve higher k coupling factors, compared with the transformer 300 in FIG. 3 where the electrically conductive structure 310 is laterally coupled with the electrically conductive structure 320. Also, the transformer 400 can allow a transmission from chip layers to BPR without using TSV vias. Another advantage of the vertical coupling is that the two electrical conductors of the transformer 400 can be more easily changed.

The coil 410 is a portion or whole of an electrically conductive layer at the backside of a support structure. The coil 410 is associated with connections 415 and 417. In some embodiments, the coil 410 is coupled to transistors by the connection 415 and coupled to a power or ground plane by the connection 417. The coil 420 is a portion or whole of another electrically conductive layer at either the frontside or the backside of a support structure. The coils 410 and 420 are in parallel along the x-axis. The coils 410 and 420 may have the same shape. The transformer 400 allows a transmission between the electrically conductive layers (e.g., from a frontside electrically conductive layer to a backside electrically conductive layer) without using vias or TSVs. This can be useful for example to avoid ESD protection and to achieve galvanic isolation (e.g., to sense high voltage signals). The coil 420 is associated with connections 425 and 427. In some embodiments, the coil 420 is coupled to transistors by the connection 425 and coupled to a power or ground plane by the connection 427.

As shown in FIG. 4, the coil 410 and coil 420 both have rectangular ring shapes. In other embodiments, the coil 410 and coil 420 may have other shapes, such as square, octagonal (using 45° lines), circle, or more complicated shapes (such as the shapes shown in FIGS. 6 and 7). The coil 410 and coil 420 may have same or different shapes or dimensions. Also, for purpose of illustration and simplicity, the transformer 400 in FIG. 4 has a 1:1 turn ratio. In other embodiments, the transformer 400 may have a different turn ratio.

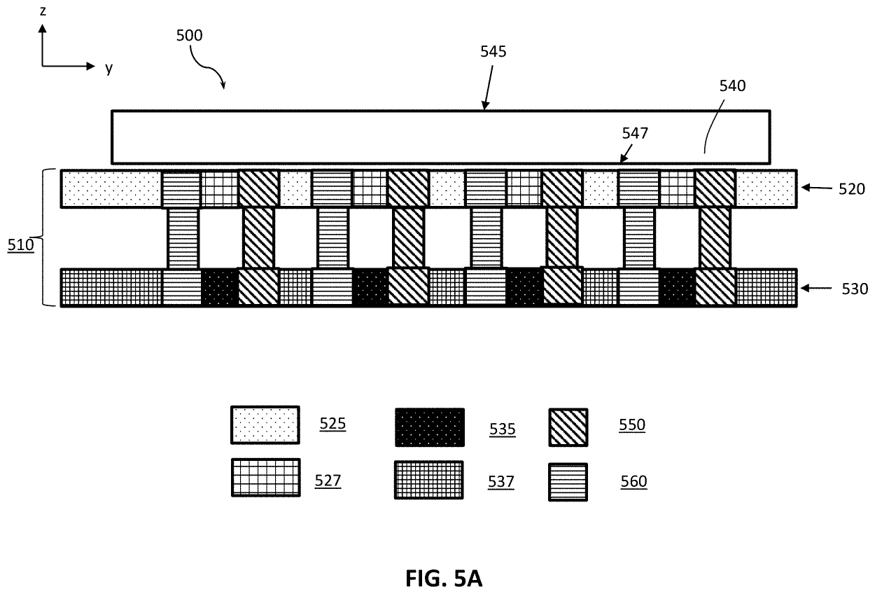

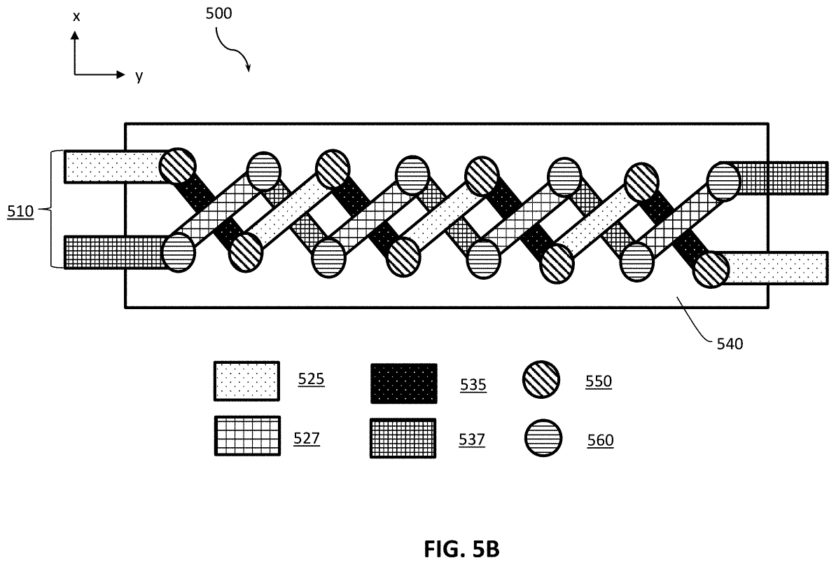

FIG. 5A is a cross-sectional view of an example IC device 500 including a transformer 510 includes two electrically conductive layers 520 and 530, according to some embodiments of the disclosure. FIG. 5B is a top view of the example IC device 500 in FIG. 5A, according to some embodiments of the disclosure. The IC device 500 also includes a support structure 540 and vias 550 and 560. In other embodiments, the IC device 500 may include other components, such as transistors, electrically conductive layers, etc.

The support structure 540 includes a semiconductor material, such as silicon. The support structure 540 may be a layer of the semiconductor material. In some embodiments, the support structure 540 facilitates formation of semiconductor structures of transistors. A semiconductor structure may be a fin, nanoribbon, nanowire, or a planar structure of a semiconductor material. In some embodiments, a semiconductor structure is formed by doping a section of the support structure 540. An example transistor is the FinFET 100 in FIG. 1 or the transistor 230 in FIG. 2.

The support structure 540 includes two surfaces 545 and 547. The surface 547 opposes the surface 545. The side of the support structure 540 from the surface 545 upwards is referred to as the frontside, and side of the support structure 540 from the surface 547 downwards is referred to as the backside of the support structure 540. The surface 545 is the frontside surface, where transistors may be placed. The surface 547 is the backside surface. Various layers, such as electrically conductive layers, can be arranged in the frontside and backside of the support structure 540. Also, semiconductor structures of transistors may be placed at the surface 545 of the support structure 540.

Two electrically conductive layers 520 and 530 are outside the support structure 540 and are at the backside. As shown in FIG. 5, the electrically conductive layer 520 is over the electrically conductive layer 530. A electrically conductive layer is a layer including a sequence of electrically conductive structures. As shown in FIGS. 5A and 5B, the electrically conductive layer 520 includes a sequence of electrically conductive structures 525 (individually referred to as “electrically conductive structure 525”) and electrically conductive structures 527 (individually referred to as “electrically conductive structure 527”). As shown in FIG. 5, the electrically conductive structures 525 and 527 are in parallel. Also, the electrically conductive structures 525 alternate with the electrically conductive structures 527. An electrically conductive structure 525 is between two adjacent electrically conductive structures 527. An electrically conductive structure 525 or 527 can be insulated from the other electrically conductive structures 525 and 527, e.g., an electrical insulator.

Similarly, the electrically conductive layer 530 includes a sequence of electrically conductive structures 535 (individually referred to as “electrically conductive structure 535”) and electrically conductive structures 537 (individually referred to as “electrically conductive structure 537”). As shown in FIG. 6, the electrically conductive structures 535 and 537 are in parallel. Also, the electrically conductive structures 535 alternate with the electrically conductive structure 537. An electrically conductive structure 535 is between two adjacent electrically conductive structures 537. An electrically conductive structure 535 or 537 can be insulated from the other electrically conductive structures 535 and 537, e.g., by an electrical insulator.

The IC structure 500 also includes vias 550 (individually referred to as “via 550”) and vias 560 (individually referred to as “via 560”). An electrically conductive structure 535 is coupled to an electrically conductive structure 525 by a via 550. An electrically conductive structure 537 is coupled to an electrically conductive structure 527 by a via 560. Accordingly, the electrically conductive structures 525 and 535 and vias 550 constitute a coil of the transformer 510. The electrically conductive structures 525 and 535 and vias 550 constitute a coil of the transformer 510. The electrically conductive structures 527 and 537 and vias 550 constitute another coil of the transformer 510. When electrical currents flow through the two coils, the transformer can generate a horizontal magnetic field, i.e., a magnetic field in a direction along the y-axis.

With the configuration of the electrical conductors in FIGS. 5A and 5B, the length of the electrical conductors can be maximized without taking more space in the support structure. The thicknesses of the electrically conductive layers 520 and 530 and a distance between the two electrically conductive layers 520 and 530 can be designed to maximize the inductance value of the transformer. Also, the coupling between different transformers and inductors can be optimized. Inductors and transformers with horizontal magnetic field have very low coupling with inductors and transformers with vertical magnetic field (e.g., the transformer 300 in FIG. 3 or the transformer 400 in FIG. 4). Accordingly, combining these devices in one chip gives more flexibility to reduce coupling on-chip level. Also, the coupling of different transformers with horizontal magnetic fields can be minimized by changing the orientation of the transformers. The coupling can be further reduced by using a circular structure. More details about the circular structure are provided below in conjunction with FIG. 7.

The electrically conductive structures 525, 527, 535 and 537 are used for delivering power, e.g., to transistors in the support structure 540. In some embodiments, one or more of the electrically conductive structures 525, 527, 535 and 537 are coupled to a power plane and another one or more of the electrically conductive structures 525, 527, 535 and 537 are coupled to a ground plane that is insulated from the power plane.

In the embodiment of FIGS. 5A and 5B, the electrical conductors of the transformer 510 are both in the support structure 540. In other embodiments, the electrical conductors of the transformer 510 include one electrically conductive layer and one electrically conductive layer outside the support structure 540.

FIG. 6A is a cross-sectional view of another example IC device 600 including a transformer 610 includes two electrically conductive layers 620 and 630, according to some embodiments of the disclosure. FIG. 6B is a top view of the example IC device 600 in FIG. 6A, according to some embodiments of the disclosure. The IC device 600 also includes a support structure 640 and TSVs 650 and 660. In other embodiments, the IC device 600 may include other components, such as transistors, electrically conductive layers, etc.

The support structure 640 may be the same as or similar to the support structure 540 in FIGS. 5A and 5B. The support structure 640 includes two surfaces 645 and 647. The surface 647 opposes the surface 645. The side of the support structure 640 from the surface 645 upwards is referred to as the frontside, and side of the support structure 640 from the surface 647 downwards is referred to as the backside of the support structure 640. Various layers, such as electrically conductive layers, can be arranged in the frontside and backside of the support structure 640. Also, semiconductor structures of transistors may be placed at the surface 645 of the support structure 640. As shown in FIG. 6A, an electrically conductive layer 630 is at the backside of the support structure 640 and adjoins the surface 647 of the support structure 640.

The electrically conductive layer 620 is at the frontside of the support structure 640. The electrically conductive layer 620 includes a sequence of electrically conductive structures 625 (individually referred to as “electrically conductive structure 625”) and electrically conductive structures 627 (individually referred to as “electrically conductive structure 627”). As shown in FIG. 6, the electrically conductive structures 625 and 627 are in parallel. Also, the electrically conductive structures 625 alternate with the electrically conductive structures 627. An electrically conductive structure 625 is between two adjacent electrically conductive structures 627. An electrically conductive structure 625 or 627 is buried in the support structure 640 and may include a conductive core including an electrically conductive material (e.g., metal) and a dielectric barrier that insulates the conductive core from the semiconductor material in the support structure 640. An electrically conductive structure 625 or 627 can be insulated from the other electrically conductive structures 625 and 627, e.g., by the dielectric barriers of the electrically conductive structures 625 and 627. Alternatively or additionally, the electrically conductive structures 625 and 627 are insulated from each other by an insulator layer, e.g., the insulator layer 227 in FIG. 2.

The electrically conductive layer 630 is a layer including an electrically conductive material, such as metal. The electrically conductive layer 630 is at the backside of the support structure 640. The electrically conductive layer 630 includes a sequence of electrical conductors 635 (individually referred to as “electrical conductor 635”) and electrical conductors 637 (individually referred to as “electrical conductor 637”). As shown in FIG. 6, the electrical conductors 635 and 637 are in parallel. Also, the electrical conductors 635 alternate with the electrical conductor 637. An electrical conductor 635 is between two adjacent electrical conductors 637. An electrical conductor 635 or 637 can be insulated from the other electrical conductors 635 and 637, e.g., by the dielectric barriers of the electrical conductors 635 and 637. Alternatively or additionally, the electrically conductive layer 630 includes electrical insulators that insulate the electrical conductors 635 and 637 from each other.

The IC structure 600 also includes TSVs 650 (individually referred to as “TSV 650”) and TSVs 660 (individually referred to as “TSV 660”). Each TSV is at least partially inside the support structure 640. A TSV 650 or 660 may extend between the surface 645 and the surface 647. An electrically conductive structure 625 is coupled to an electrical conductor 635 by a TSV 650. An electrically conductive structure 627 is coupled to an electrical conductor 637 by a TSV 660. Accordingly, the electrically conductive structures 625, electrical conductors 635, and TSVs 650 constitute an electrical conductor of the transformer 610. The electrically conductive structures 627, electrical conductors 637, and TSVs 660 constitute another electrical conductor of the transformer 610. When electrical currents flow through the two electrical conductors, the transformer can generate a horizontal magnetic field, i.e., a magnetic field in a direction along the y-axis. In the embodiment of FIGS. 6A and 6B, the electrically conductive layer 630 is at the backside of the support structure 640. In other embodiments, the electrically conductive layer 630 may be at the frontside of the support structure 640 and the electrically conductive structures 625 and 627 can be coupled to the electrical conductors 635 and 637 by vias.

With the configuration of the electrical conductors in FIGS. 6A and 6B, the length of the electrical conductors can be maximized without taking more space in the support structure. The thicknesses of the electrically conductive layer 620 and a distance between the electrically conductive layers 620 and electrically conductive layer 630 can be designed to maximize the inductance value of the transformer. Also, the coupling between different transformers and inductors can be optimized. Inductors and transformers with horizontal magnetic field have very low coupling with inductors and transformers with vertical magnetic field (e.g., the transformer 300 in FIG. 3 or the transformer 400 in FIG. 4). Accordingly, combining these devices in one chip gives more flexibility to reduce coupling on-chip level. Also, the coupling of different transformers with horizontal magnetic fields can be minimized by changing the orientation of the transformers.

The electrically conductive structures 625 and 627 are used for delivering power, e.g., to transistors in the support structure 640. In some embodiments, one or more of the electrically conductive structures 625 and 627 are coupled to a power plane and another one or more of the electrically conductive structures 625 and 627 are coupled to a ground plane that is insulated from the power plane.

FIG. 7 illustrates an example transformer 700 formed based on electrically conductive layers, according to some embodiments of the disclosure. The transformer 700 may be an embodiment of the transformer 510 in FIGS. 5A and 5B or the transformer 610 in FIGS. 6A and 6B. The coils of the transformer 700 forms a ring shape to optimize/reduce magnetic coupling with other transformers that can be arranged on the same chip as the transformer 700.

The transformer 700 in FIG. 7 includes a first coil that includes electrically conductive structures 725, 735, and vias 750 and a second coil that includes electrically conductive structures 727, 737, and vias 750. An electrically conductive structure is a structure (e.g., an elongated structure) including an electrically conductive material, such as metal. An electrically conductive structure may be a portion of an electrically conductive layer outside a support structure. The electrically conductive structures 725 and 727 are in a first layer, which is over a second layer that includes the electrically conductive structures 735 and 737. An example of the first layer is the electrically conductive layer 520 in FIGS. 5A and 5B or the electrically conductive layer 620 in FIGS. 6A and 6B. An example of the second layer is the electrically conductive layer 530 in FIGS. 5A and 5B or the electrically conductive layer 630 in FIGS. 6A and 6B.

As shown in FIG. 7, the electrically conductive structures 725 alternate with the electrically conductive structures 727. An electrically conductive structure 727 is between two adjacent electrically conductive structures 725. Also, the electrically conductive structures 735 alternate with the electrically conductive structures 737. An electrically conductive structure 737 is between two adjacent electrically conductive structures 735. The first coil has two coupling structures 775 and 785 at two ends of the first coil. The second coil has two coupling structures 785 and 787 at two ends of the second coil. A coupling structure of a coil can couple the coil to other devices or components in the same IC device, such as semiconductor devices.

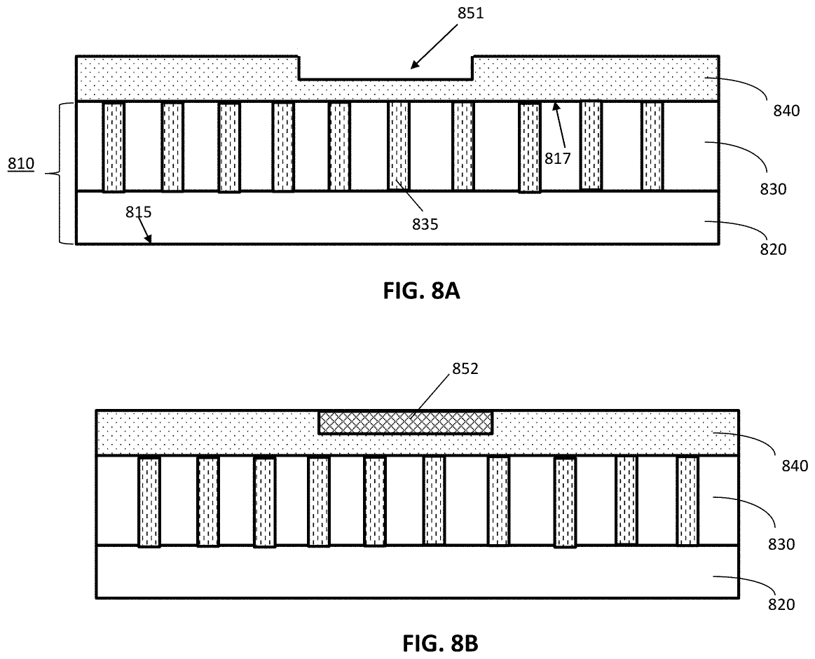

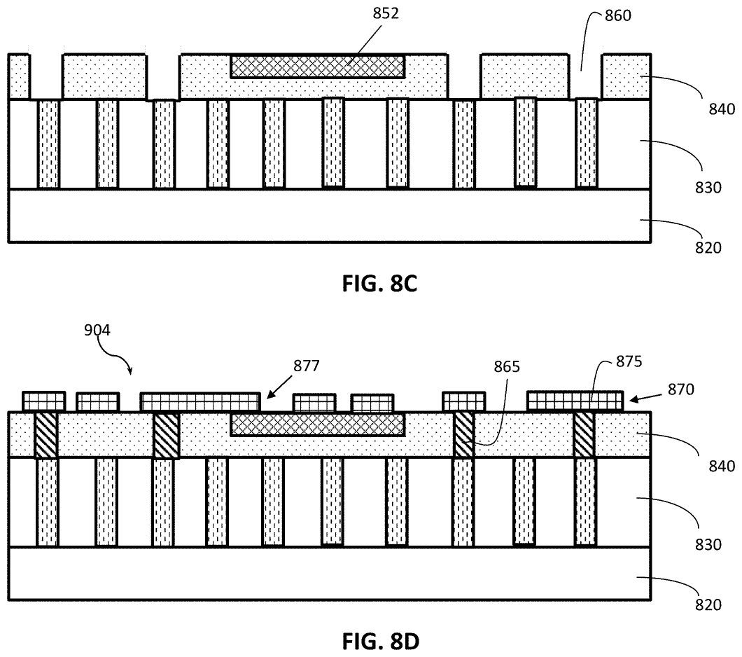

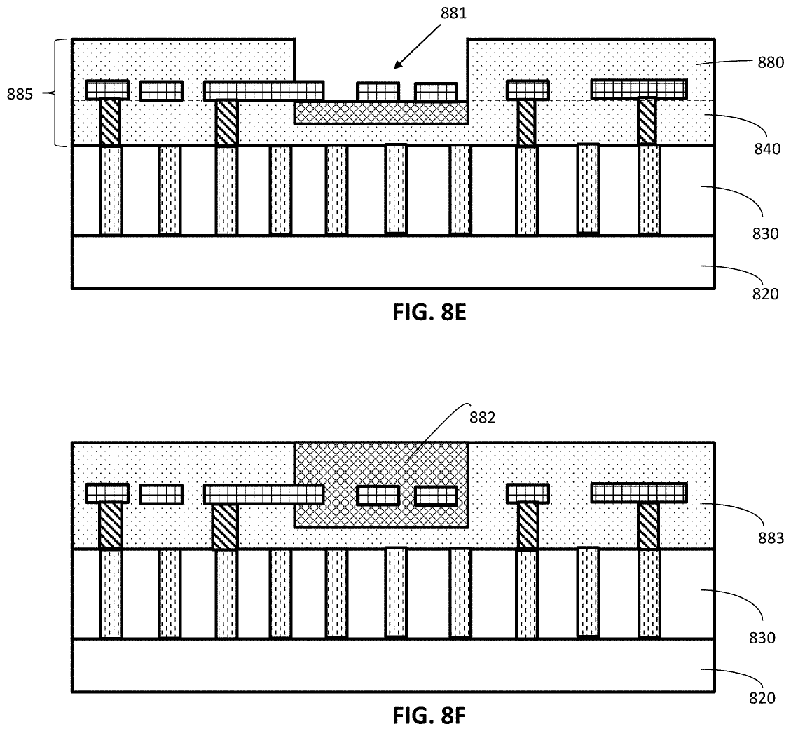

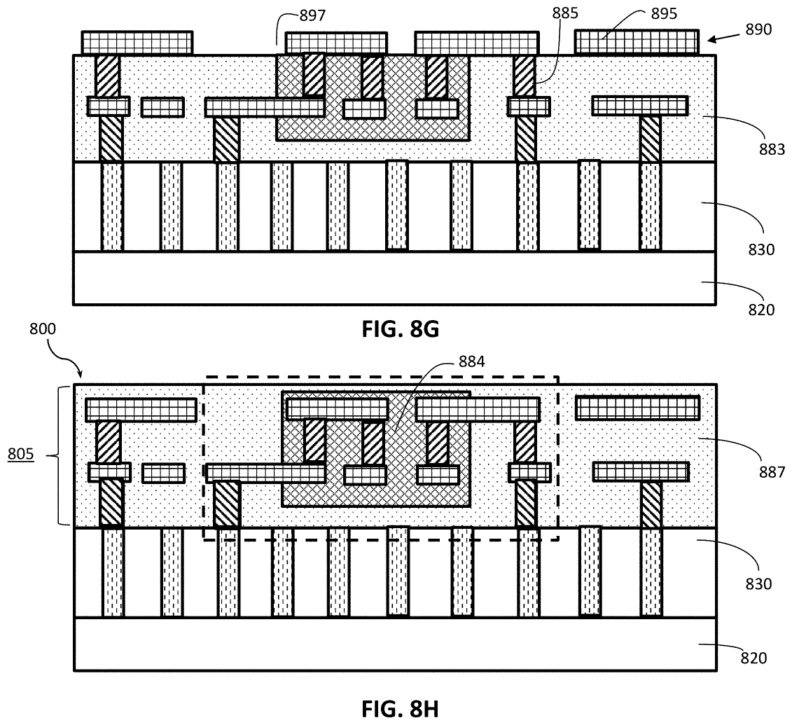

FIGS. 8A-8H illustrate a process of forming an inductor at a backside of a support structure 810 where BPRs are buried, according to some embodiments of the disclosure. The support structure 810 includes a first layer 820 and a second layer 830. The first layer 820 includes a plurality of semiconductor devices (not shown in FIGS. 8A-8H), such as transistors. The second layer 830 includes TSVs 835. The support structure 810 also includes BPRs (not shown in FIGS. 8A-8H) coupled to the transistors. A part of a BPR or the whole BPR is in the first layer 820. In some embodiments, a part of a BPR may be in the second layer 830. The support structure 810 includes a semiconductor material, such as silicon. In some embodiments, the support structure 810 facilitates formation of semiconductor structures of transistors. A semiconductor structure may be a fin, nanoribbon, nanowire, or a planar structure of a semiconductor material. In some embodiments, a semiconductor structure is formed by doping a section of the support structure 810. An example transistor is the FinFET 100 in FIG. 1 or the transistor 230 in FIG. 2. The support structure 810 includes two surfaces 815 and 817. The surface 817 opposes the surface 815. The side of the support structure 810 from the surface 815 downwards in FIG. 9 is referred to as the frontside, and side of the support structure 810 from the surface 817 upwards in FIG. 9 is referred to as the backside of the support structure 810. Various layers, such as electrically conductive layers, can be arranged in the frontside and backside of the support structure 810. Also, semiconductor structures of transistors may be placed at the surface 815 of the support structure 810.

In FIG. 8A, a dielectric layer 840 is formed at the backside of the support structure 810. The dielectric layer 840 is a layer including a dielectric material that can be used as an electrical insulator. An example of the dielectric material is oxide materials, such as silicon oxide. A gap 851 is formed in the dielectric layer 840. In FIG. 8B, the gap 851 is filled with a magnetic material, which forms a magnetic core 852. In FIG. 8C, openings 860 (individually referred to as “opening 860”) are formed in the dielectric layer 840, particularly in the dielectric material of the dielectric layer 840. In some embodiments, the openings 860 are formed by removing the dielectric material from predetermined portions of the dielectric layer 840, e.g., through an etching process.

After the formation of openings 860, a first redistributed layer is formed in FIG. 8D. The first redistributed layer includes vias 865 formed in the openings 860 and an electrically conductive layer 870. The electrically conductive layer 870 includes an electrically conductive material, such as metal. The electrically conductive layer 870 includes electrically conductive sections 875 (individually referred to as “electrically conductive section 875”) and gaps 877 (individually referred to as “gap 877”) between the electrically conductive sections 875. A gap 877 is present between two adjacent electrically conductive sections 875. Each via 865 is connected to an electrically conductive section 875.

In FIG. 8E, another dielectric layer 880 is formed on top of the dielectric layer 840. The dielectric layer 880 may include the dielectric material of the dielectric layer 840 or a different dielectric material. The dielectric material of the dielectric layer 880 fills the gaps 877 between the electrically conductive sections 875 of the electrically conductive layer 870. The dielectric material can insulate the electrically conductive sections 875 from each other. Also, a gap 881 is formed in the dielectric layer 880. In FIG. 8F, the gap 881 is filled with the magnetic material and the magnetic core 852 is converted to a magnetic core 882. The dielectric layers 840 and 880 may become one integrated dielectric layer 883.

After the formation of the dielectric layer 880, a second redistributed layer is formed in FIG. 8G. Similar to the first redistributed layer, the second redistributed layer is formed by forming openings (not shown in FIGS. 8A-H) in the dielectric layer 883 and forming vias 885 in the openings. The second redistributed layer includes the vias 855 and an electrically conductive layer 890 formed on the dielectric layer 883. The electrically conductive layer 890 adjoins the dielectric layer 883. The electrically conductive layer 890 includes an electrically conductive material, such as metal. The electrically conductive layer 890 includes electrically conductive sections 895 (individually referred to as “electrically conductive section 895”) and gaps 897 (individually referred to as “gap 897”) between the electrically conductive sections 895. A gap 897 is present between two adjacent electrically conductive sections 895. Each via 885 is connected to an electrically conductive section 895.

In FIG. 8H, an IC device 800 is formed. A new magnetic core 884 is formed by adding more magnetic material to magnetic core 882. Also, the dielectric layer 883 is topped to form a new dielectric layer 887. The dielectric layer 887 encloses the electrically conductive layers 870 and 890, vias 865 and 885, and magnetic core 882. The dielectric layer 887, electrically conductive layers 870 and 890, vias 865 and 885, and magnetic core 882 constitute a structure 805. The structure 805 adjoins the surface 817 of the support structure 810 and is at the backside of the support structure 810. The structure 805 is also referred to as a backside structure. The dielectric material in the dielectric layer 887 insulates the electrically conductive layers 870 and 890, vias 865 and 885, and magnetic core 882 from each other. The magnetic core 882 is coupled to some of the electrically conductive sections 875 and 895 and vias 865 and 885. These electrically conductive sections 875 and 895 and vias 865 and 885, which are in the dotted rectangular in FIG. 8H, constitute the coil of the inductor. As an electrical current flows through the coil, the magnetic core 882 can generate a magnetic field. Even though the process in FIGS. 8A-H forms an inductor, the process can also be used to form transformers in IC devices.

One or more electrically conductive sections 875 or 895 and one or more vias 865 or 885 can constitute a power plane of the IC device 800. Similarly, one or more electrically conductive sections 875 or 895 and one or more vias 865 or 885 can constitute a ground plane of the IC device 800. Thus, the first and second redistributed layers can be used for power plane, ground plane, and inductor coil. BPRs buried in the support structure 810 can be coupled to the power and ground planes by TSVs 935 and be used to deliver power to the transitions. As the power and ground plane are in the dielectric layer 887, which is at the backside of the support structure 810, the IC device 800 has backside power supply. The backside power supply is realized by the connection of the TSVs 835 to the redistributed layers. As, the inductor coil is also created in the redistributed layers, additional BPRs can be coupled to the inductor coil by additional TSVs and deliver power to the inductor coil. In some embodiments, cavities formed in the dielectric material of the dielectric layer 887 can be filled with magnetic paste to improve the coupling of the inductor coil or improve the inductor performance.

FIG. 9 is a cross-sectional view of an example IC device 900 formed by the process in FIGS. 8A-H, according to some embodiments of the disclosure. The IC device 900 includes a support structure 910 and a backside structure 920. In other embodiments, the IC device 900 may include fewer, more, or different components.

The support structure 910 includes transistors 925 (individually referred to as “transistor 925”), BPRs 930A-D (collectively referred to as “BPRs 930” or “BPR 930”), and TSVs 935A-D (collectively referred to as “TSVs 935” or “TSV 935”). The support structure 910 is an embodiment of the support structure 810 in FIGS. 8A-H. The support structure 910 includes the transistors 925, BPRs 930, and TSVs 935. The transistors 925 are in an active layer inside the support structure 910. The support structure 910 includes two surfaces 915 and 917. The surface 917 opposes the surface 915. The side of the support structure 910 from the surface 915 downwards in FIG. 9 is referred to as the frontside, and side of the support structure 910 from the surface 917 upwards in FIG. 9 is referred to as the backside of the support structure 910. Various layers, such as electrically conductive layers, can be arranged in the frontside and backside of the support structure 910. Also, semiconductor structures of transistors may be placed at the surface 915 of the support structure 910.

The backside structure 920 includes a dielectric layer 985, a power plane, a ground plane, and an inductor. The backside structure 920 is an embodiment of the structure 805 in FIG. 8H. The dielectric layer 985 is an embodiment of the dielectric layer 887 in FIG. 8H. The dielectric layer 985 is at the backside of the support structure 910 and adjoins the surface 917 of the support structure 910. The dielectric layer 985 includes the power plane, ground plane, and inductor. The dielectric material in the dielectric layer 985 insulates components of the power plane, ground plane, and inductor from each other.

As shown in FIG. 9, the inductor includes a magnetic core 982 and a coil that includes electrically conductive sections 940 (individually referred to as “electrically conductive section 940”) and vias 945 (individually referred to as “via 945”). The magnetic core 982 is coupled to the coil. As an electrical current flows through the coil, a magnetic field is generated by the magnetic core 982. The magnetic core 982 is an embodiment of the magnetic core 884 in FIG. 8. An electrically conductive section 940 is an embodiment of an electrically conductive section 895 in FIG. 8H. A via 945 is an embodiment of a via 865 or 885 in FIG. 8H. The power plane includes electrically conductive sections 950 (individually referred to as “electrically conductive section 950”) and vias 955 (individually referred to as “via 955”). An electrically conductive section 950 is an embodiment of an electrically conductive section 895 in FIG. 8H. A via 955 is an embodiment of a via 865 or 885 in FIG. 8H. The ground plane includes an electrically conductive sections 960 and a via 965. The electrically conductive section 960 is an embodiment of an electrically conductive section 895 in FIG. 8H. The via 965 is an embodiment of a via 865 or 885 in FIG. 8H.

The BPRs 930 are buried in the support structure 910. Each BPR 930 is connected to a TSV 935 in the support structure 910. The BPRs 930 are coupled to the transistors 925. The BPR 930A is coupled to the power plane by the TSV 935A. The BPR 930D is coupled to the ground plane by the TSV 935D. The BPRs 930A and 930D can deliver power to some or all of the transistors 925. The BPRs 930B-C are coupled to the coil of the inductor by TSVs 935B-C. The BPRs 930B-C can delivery power to the coil of the inductor.

In FIG. 9, a TSV 935 has a longitudinal axis perpendicular (or substantially perpendicular) to the surface 915 or 917. The TSV 935 extends between the surface 915 and the surface 917 but is not through the whole distance from the surface 915 to the surface 917. In other embodiments, the IC device 900 does not include BPRs 930B-C. The coil of the inductor is connected to TSVs that extend between the surface 915 and the surface 917. The TSVs couple the coil to a semiconductor device.

FIG. 10 is a cross-sectional view of another example IC device 1000 formed by the process in FIGS. 8A-H, according to some embodiments of the disclosure. The IC device 1000 includes a support structure 1010 and a backside structure 1020. In other embodiments, the IC device 1000 may include fewer, more, or different components.

The support structure 1010 includes transistors 1025 (individually referred to as “transistor 1025”), BPRs 1030A-D (collectively referred to as “BPRs 1030” or “BPR 1030”), and TSVs 1035A-D (collectively referred to as “TSVs 1035” or “TSV 1035”). The support structure 1010 is an embodiment of the support structure 810 in FIGS. 8A-H. The support structure 1010 includes the transistors 1025, BPRs 1030, and TSVs 1035. The transistors 1025 are in an active layer inside the support structure 1010. The support structure 1010 includes two surfaces 1015 and 1017. The surface 1017 opposes the surface 1015. The side of the support structure 1010 from the surface 1015 downwards in FIG. 10 is referred to as the frontside, and side of the support structure 1010 from the surface 1017 upwards in FIG. 10 is referred to as the backside of the support structure 1010. Various layers, such as electrically conductive layers, can be arranged in the frontside and backside of the support structure 1010. Also, semiconductor structures of transistors may be placed at the surface 1015 of the support structure 1010.

The backside structure 1020 includes a dielectric layer 1085, a power plane, a ground plane, and a transformer. The backside structure 1020 is an embodiment of the structure 805 in FIG. 8H. The dielectric layer 1085 is an embodiment of the dielectric layer 887 in FIG. 8H. The dielectric layer 1085 is at the backside of the support structure 1010 and adjoins the surface 1017 of the support structure 1010. The dielectric layer 1085 includes the power plane, ground plane, and transformer. The dielectric material in the dielectric layer 1085 insulates components of the power plane, ground plane, and transformer from each other.

As shown in FIG. 10, the transformer includes a magnetic core 1082, a first coil that includes electrically conductive sections 1040 (individually referred to as “electrically conductive section 1040”) and vias 1045 (individually referred to as “via 1045”), and a second coil that includes electrically conductive sections 1070 (individually referred to as “electrically conductive section 1070”) and vias 1075 (individually referred to as “via 1075”). The magnetic core 1082 is coupled to the first and second coils. As an electrical current flows through first and second coils, magnetic fields can be generated by the magnetic core 982. The magnetic core 1082 is an embodiment of the magnetic core 884 in FIG. 8. An electrically conductive section 1040 or 1070 is an embodiment of an electrically conductive section 895 in FIG. 8H. A via 1045 or 1075 is an embodiment of a via 865 or 885 in FIG. 8H. The power plane includes electrically conductive sections 1050 (individually referred to as “electrically conductive section 1050”) and vias 1055 (individually referred to as “via 1055”). An electrically conductive section 1050 is an embodiment of an electrically conductive section 895 in FIG. 8H. A via 1055 is an embodiment of a via 865 or 885 in FIG. 8H. The ground plane includes an electrically conductive sections 1060 and a via 1065. The electrically conductive section 1060 is an embodiment of an electrically conductive section 895 in FIG. 8H. The via 1065 is an embodiment of a via 865 or 885 in FIG. 8H.

The BPRs 1030 are buried in the support structure 1010. Each BPR 1030 is connected to a TSV 1035 in the support structure 1010. The BPRs 1030 are coupled to the transistors 1025. The BPR 1030A is coupled to the power plane by the TSV 1035A. The BPR 1030D is coupled to the ground plane by the TSV 1035D. The BPRs 1030A and 1030D can deliver power to some or all of the transistors 1025. The BPRs 1030B-C are coupled to the first coil of the transformer by TSVs 1035B-C. The BPRs 1030B-C can delivery power to the first coil of the transformer. Similarly, The BPRs 1030D-E are coupled to the first coil of the transformer by TSVs 1035D-E. The BPRs 1030D-E can delivery power to the first coil of the transformer.

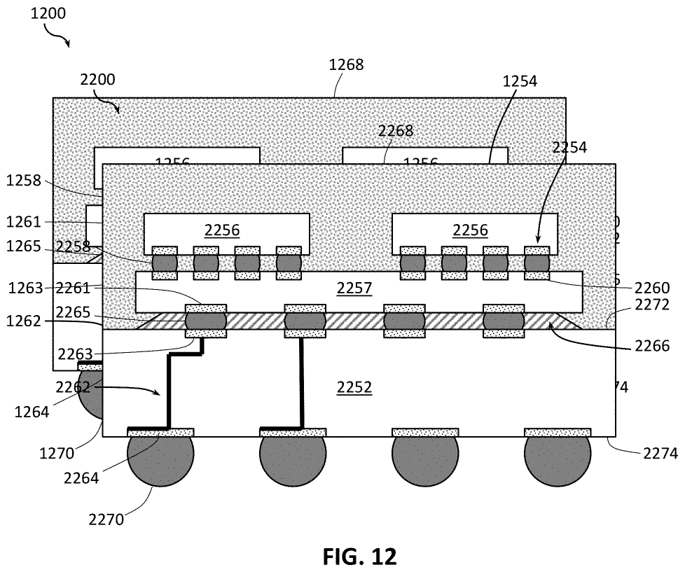

FIGS. 11A-11B are top views of a wafer 2000 and dies 2002 that may include one or more transformers that includes two electrically conductive layers, according to some embodiments of the disclosure. In some embodiments, the dies 2002 may be included in an IC package, according to some embodiments of the disclosure. For example, any of the dies 2002 may serve as any of the dies 2256 in an IC package 2200 shown in FIG. 12. The wafer 2000 may be composed of semiconductor material and may include one or more dies 2002 having IC devices formed on a surface of the wafer 2000. Each of the dies 2002 may be a repeating unit of a semiconductor product that includes any suitable IC (e.g., ICs including one or more BPRs as described herein). After the fabrication of the semiconductor product is complete (e.g., after manufacture of one or more BPRs as described herein), the wafer 2000 may undergo a singulation process in which each of the dies 2002 is separated from one another to provide discrete “chips” of the semiconductor product. In particular, devices that include one or more BPRs as disclosed herein may take the form of the wafer 2000 (e.g., not singulated) or the form of the die 2002 (e.g., singulated). The die 2002 may include one or more diodes (e.g., one or more BPRs as described herein), one or more transistors (e.g., one or more III-N transistors as described herein) as well as, optionally, supporting circuitry to route electrical signals to the III-N diodes with n-doped wells and capping layers and III-N transistors, as well as any other IC components. In some embodiments, the wafer 2000 or the die 2002 may implement an electrostatic discharge (ESD) protection device, an RF FE device, a memory device (e.g., a static random-access memory (SRAM) device), a logic device (e.g., an AND, OR, NAND, or NOR gate), or any other suitable circuit element. Multiple ones of these devices may be combined on a single die 2002.

FIG. 12 is a side, cross-sectional view of an example IC package 2200 that may include one or more IC devices having transformers that includes two electrically conductive layers, according to some embodiments of the disclosure. In some embodiments, the IC package 2200 may be a system-in-package (SiP).

As shown in FIG. 12, the IC package 2200 may include a package substrate 2252. The package substrate 2252 may be formed of a dielectric material (e.g., a ceramic, a glass, a combination of organic and inorganic materials, a buildup film, an epoxy film having filler particles therein, etc., and may have embedded portions having different materials), and may have conductive pathways extending through the dielectric material between the face 2272 and the face 2274, or between different locations on the face 2272, and/or between different locations on the face 2274.

The package substrate 2252 may include conductive contacts 2263 that are coupled to conductive pathways 2262 through the package substrate 2252, allowing circuitry within the dies 2256 and/or the interposer 2257 to electrically couple to various ones of the conductive contacts 2264 (or to other devices included in the package substrate 2252, not shown).

The IC package 2200 may include an interposer 2257 coupled to the package substrate 2252 via conductive contacts 2261 of the interposer 2257, first-level interconnects 2265, and the conductive contacts 2263 of the package substrate 2252. The first-level interconnects 2265 illustrated in FIG. 12 are solder bumps, but any suitable first-level interconnects 2265 may be used. In some embodiments, no interposer 2257 may be included in the IC package 2200; instead, the dies 2256 may be coupled directly to the conductive contacts 2263 at the face 2272 by first-level interconnects 2265.

The IC package 2200 may include one or more dies 2256 coupled to the interposer 2257 via conductive contacts 2254 of the dies 2256, first-level interconnects 2258, and conductive contacts 2260 of the interposer 2257. The conductive contacts 2260 may be coupled to conductive pathways (not shown) through the interposer 2257, allowing circuitry within the dies 2256 to electrically couple to various ones of the conductive contacts 2261 (or to other devices included in the interposer 2257, not shown). The first-level interconnects 2258 illustrated in FIG. 12 are solder bumps, but any suitable first-level interconnects 2258 may be used. As used herein, a “conductive contact” may refer to a portion of electrically conductive material (e.g., metal) serving as an interface between different components; conductive contacts may be recessed in, flush with, or extending away from a surface of a component, and may take any suitable form (e.g., a conductive pad or socket).

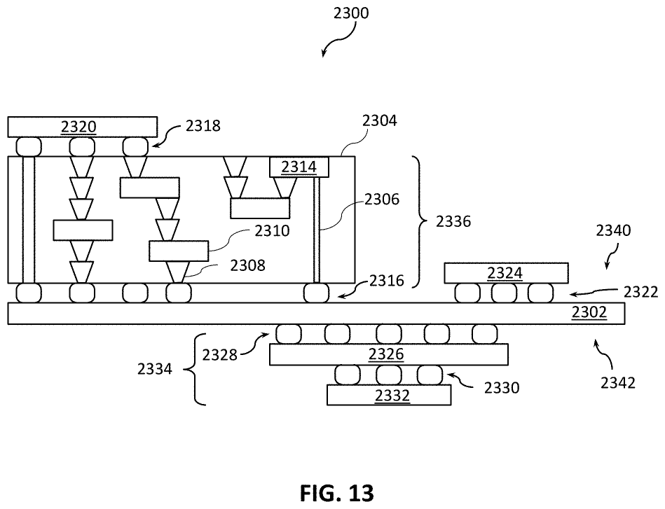

In some embodiments, an underfill material 2266 may be disposed between the package substrate 2252 and the interposer 2257 around the first-level interconnects 2265, and a mold compound 2268 may be disposed around the dies 2256 and the interposer 2257 and in contact with the package substrate 2252. In some embodiments, the underfill material 2266 may be the same as the mold compound 2268. Example materials that may be used for the underfill material 2266 and the mold compound 2268 are epoxy mold materials, as suitable. Second-level interconnects 2270 may be coupled to the conductive contacts 2264. The second-level interconnects 2270 illustrated in FIG. 12 are solder balls (e.g., for a ball grid array arrangement), but any suitable second-level interconnects 22770 may be used (e.g., pins in a pin grid array arrangement or lands in a land grid array arrangement). The second-level interconnects 2270 may be used to couple the IC package 2200 to another component, such as a circuit board (e.g., a motherboard), an interposer, or another IC package, as known in the art and as discussed below with reference to FIG. 13.

The dies 2256 may take the form of any of the embodiments of the die 2002 discussed herein and may include any of the embodiments of an IC device having one or more BPRs. In embodiments in which the IC package 2200 includes multiple dies 2256, the IC package 2200 may be referred to as a multi-chip package. Importantly, even in such embodiments of an MCP implementation of the IC package 2200, one or more BPRs may be provided in a single chip, in accordance with any of the embodiments described herein. The dies 2256 may include circuitry to perform any desired functionality. For example, one or more of the dies 2256 may be ESD protection dies, including one or more BPRs as described herein, one or more of the dies 2256 may be logic dies (e.g., silicon-based dies), one or more of the dies 2256 may be memory dies (e.g., high bandwidth memory), etc. In some embodiments, any of the dies 2256 may include one or more BPRs, e.g., as discussed above; in some embodiments, at least some of the dies 2256 may not include any III-N diodes with n-doped wells and capping layers.

The IC package 2200 illustrated in FIG. 12 may be a flip chip package, although other package architectures may be used. For example, the IC package 2200 may be a ball grid array (BGA) package, such as an embedded wafer-level ball grid array (eWLB) package. In another example, the IC package 2200 may be a wafer-level chip scale package (WLCSP) or a panel fan-out (FO) package. Although two dies 2256 are illustrated in the IC package 2200 of FIG. 12, an IC package 2200 may include any desired number of the dies 2256. An IC package 2200 may include additional passive components, such as surface-mount resistors, capacitors, and inductors disposed on the first face 2272 or the second face 2274 of the package substrate 2252, or on either face of the interposer 2257. More generally, an IC package 2200 may include any other active or passive components known in the art.

FIG. 13 is a cross-sectional side view of an IC device assembly 2300 that may include components having one or more IC devices implementing transformers that includes two electrically conductive layers, according to some embodiments of the disclosure. The IC device assembly 2300 includes a number of components disposed on a circuit board 2302 (which may be, e.g., a motherboard). The IC device assembly 2300 includes components disposed on a first face 2340 of the circuit board 2302 and an opposing second face 2342 of the circuit board 2302; generally, components may be disposed on one or both faces 2340 and 2342. In particular, any suitable ones of the components of the IC device assembly 2300 may include any of the IC devices implementing one or more BPRs in accordance with any of the embodiments disclosed herein; e.g., any of the IC packages discussed below with reference to the IC device assembly 2300 may take the form of any of the embodiments of the IC package 2200 discussed above with reference to FIG. 12 (e.g., may include one or more BPRs in/on a die 2256).

In some embodiments, the circuit board 2302 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 2302. In other embodiments, the circuit board 2302 may be a non-PCB substrate.

The IC device assembly 2300 illustrated in FIG. 13 includes a package-on-interposer structure 2336 coupled to the first face 2340 of the circuit board 2302 by coupling components 2316. The coupling components 2316 may electrically and mechanically couple the package-on-interposer structure 2336 to the circuit board 2302, and may include solder balls (e.g., as shown in FIG. 13), male and female portions of a socket, an adhesive, an underfill material, and/or any other suitable electrical and/or mechanical coupling structure.

The package-on-interposer structure 2336 may include an IC package 2320 coupled to an interposer 2304 by coupling components 2318. The coupling components 2318 may take any suitable form for the application, such as the forms discussed above with reference to the coupling components 2316. The IC package 2320 may be or include, for example, a die (the die 2002 of FIG. 11B), an IC device (e.g., the IC device of FIGS. 1-2), or any other suitable component. In particular, the IC package 2320 may include one or more BPRs as described herein. Although a single IC package 2320 is shown in FIG. 13, multiple IC packages may be coupled to the interposer 2304; indeed, additional interposers may be coupled to the interposer 2304. The interposer 2304 may provide an intervening substrate used to bridge the circuit board 2302 and the IC package 2320. Generally, the interposer 2304 may spread a connection to a wider pitch or reroute a connection to a different connection. For example, the interposer 2304 may couple the IC package 2320 (e.g., a die) to a BGA of the coupling components 2316 for coupling to the circuit board 2302. In the embodiment illustrated in FIG. 13, the IC package 2320 and the circuit board 2302 are attached to opposing sides of the interposer 2304; in other embodiments, the IC package 2320 and the circuit board 2302 may be attached to a same side of the interposer 2304. In some embodiments, three or more components may be interconnected by way of the interposer 2304.

The interposer 2304 may be formed of an epoxy resin, a fiberglass-reinforced epoxy resin, a ceramic material, or a polymer material such as polyimide. In some implementations, the interposer 2304 may be formed of alternate rigid or flexible materials that may include the same materials described above for use in a semiconductor substrate, such as silicon, germanium, and other group III-V and group IV materials. The interposer 2304 may include metal interconnects 2308 and vias 2310, including but not limited to TSVs 2306. The interposer 2304 may further include embedded devices 2314, including both passive and active devices. Such devices may include, but are not limited to, capacitors, decoupling capacitors, resistors, inductors, fuses, diodes, transformers, sensors, ESD protection devices, and memory devices. More complex devices such as further RF devices, power amplifiers, power management devices, antennas, arrays, sensors, and microelectromechanical systems (MEMS) devices may also be formed on the interposer 2304. In some embodiments, the IC devices implementing one or more BPRs as described herein may also be implemented in/on the interposer 2304. The package-on-interposer structure 2336 may take the form of any of the package-on-interposer structures known in the art.

The IC device assembly 2300 may include an IC package 2324 coupled to the first face 2340 of the circuit board 2302 by coupling components 2322. The coupling components 2322 may take the form of any of the embodiments discussed above with reference to the coupling components 2316, and the IC package 2324 may take the form of any of the embodiments discussed above with reference to the IC package 2320.

The IC device assembly 2300 illustrated in FIG. 13 includes a package-on-package structure 2334 coupled to the second face 2342 of the circuit board 2302 by coupling components 2328. The package-on-package structure 2334 may include an IC package 2326 and an IC package 2332 coupled together by coupling components 2330 such that the IC package 2326 is disposed between the circuit board 2302 and the IC package 2332. The coupling components 2328 and 2330 may take the form of any of the embodiments of the coupling components 2316 discussed above, and the IC packages 2326 and 2332 may take the form of any of the embodiments of the IC package 2320 discussed above. The package-on-package structure 2334 may be configured in accordance with any of the package-on-package structures known in the art.

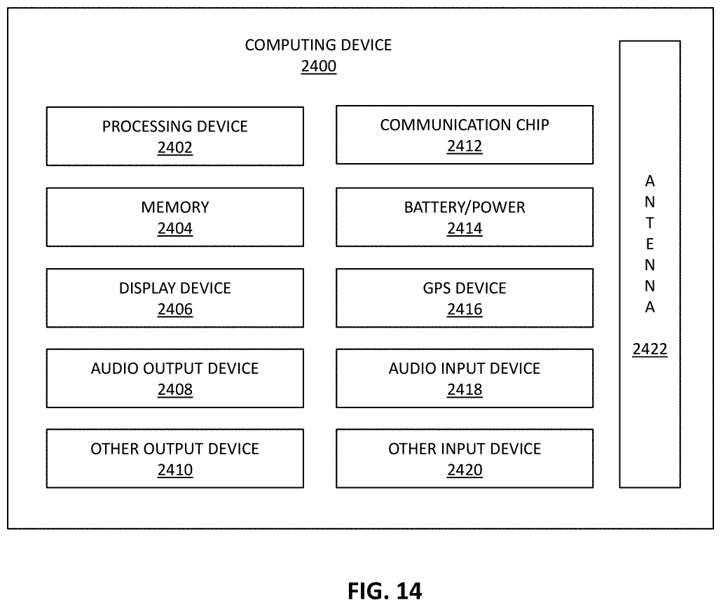

FIG. 14 is a block diagram of an example computing device 2400 that may include one or more components with one or more IC devices having one or more BPRs, according to some embodiments of the disclosure. For example, any suitable ones of the components of the computing device 2400 may include a die (e.g., the die 2002 of FIG. 11B) including one or more BPRs, according to some embodiments of the disclosure. Any of the components of the computing device 2400 may include an IC device (e.g., any embodiment of the IC devices of FIGS. 1-4) and/or an IC package (e.g., the IC package 2200 of FIG. 12). Any of the components of the computing device 2400 may include an IC device assembly (e.g., the IC device assembly 2300 of FIG. 13).

A number of components are illustrated in FIG. 14 as included in the computing device 2400, but any one or more of these components may be omitted or duplicated, as suitable for the application. In some embodiments, some or all of the components included in the computing device 2400 may be attached to one or more motherboards. In some embodiments, some or all of these components are fabricated onto a single SoC die.

Additionally, in various embodiments, the computing device 2400 may not include one or more of the components illustrated in FIG. 14, but the computing device 2400 may include interface circuitry for coupling to the one or more components. For example, the computing device 2400 may not include a display device 2406, but may include display device interface circuitry (e.g., a connector and driver circuitry) to which a display device 2406 may be coupled. In another set of examples, the computing device 2400 may not include an audio input device 2418 or an audio output device 2408, but may include audio input or output device interface circuitry (e.g., connectors and supporting circuitry) to which an audio input device 2418 or audio output device 2408 may be coupled.

The computing device 2400 may include a processing device 2402 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 2402 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices. The computing device 2400 may include a memory 2404, which may itself include one or more memory devices such as volatile memory (e.g., DRAM), nonvolatile memory (e.g., read-only memory (ROM)), flash memory, solid-state memory, and/or a hard drive. In some embodiments, the memory 2404 may include memory that shares a die with the processing device 2402. This memory may be used as cache memory and may include, e.g., eDRAM, and/or spin transfer torque magnetic random-access memory (STT-MRAM).

In some embodiments, the computing device 2400 may include a communication chip 2412 (e.g., one or more communication chips). For example, the communication chip 2412 may be configured for managing wireless communications for the transfer of data to and from the computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 2412 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 2412 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 2412 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 2412 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 2412 may operate in accordance with other wireless protocols in other embodiments. The computing device 2400 may include an antenna 2422 to facilitate wireless communications and/or to receive other wireless communications (such as AM or FM radio transmissions).

In some embodiments, the communication chip 2412 may manage wired communications, such as electrical, optical, or any other suitable communication protocols (e.g., the Ethernet). As noted above, the communication chip 2412 may include multiple communication chips. For instance, a first communication chip 2412 may be dedicated to shorter-range wireless communications such as Wi-Fi or Bluetooth, and a second communication chip 2412 may be dedicated to longer-range wireless communications such as global positioning system (GPS), EDGE, GPRS, CDMA, WiMAX, LTE, EV-DO, or others. In some embodiments, a first communication chip 2412 may be dedicated to wireless communications, and a second communication chip 2412 may be dedicated to wired communications.

In various embodiments, IC devices having one or more BPRs as described herein may be particularly advantageous for use as part of ESD circuits protecting power amplifiers, low-noise amplifiers, filters (including arrays of filters and filter banks), switches, or other active components. In some embodiments, IC devices having one or more BPRs as described herein may be used in PMICs, e.g., as a rectifying diode for large currents. In some embodiments, IC devices having one or more BPRs as described herein may be used in audio devices and/or in various input/output devices.

The computing device 2400 may include battery/power circuitry 2414. The battery/power circuitry 2414 may include one or more energy storage devices (e.g., batteries or capacitors) and/or circuitry for coupling components of the computing device 2400 to an energy source separate from the computing device 2400 (e.g., AC line power).

The computing device 2400 may include a display device 2406 (or corresponding interface circuitry, as discussed above). The display device 2406 may include any visual indicators, such as a heads-up display, a computer monitor, a projector, a touchscreen display, a liquid crystal display (LCD), a light-emitting diode display, or a flat panel display, for example.

The computing device 2400 may include an audio output device 2408 (or corresponding interface circuitry, as discussed above). The audio output device 2408 may include any device that generates an audible indicator, such as speakers, headsets, or earbuds, for example.

The computing device 2400 may include an audio input device 2418 (or corresponding interface circuitry, as discussed above). The audio input device 2418 may include any device that generates a signal representative of a sound, such as microphones, microphone arrays, or digital instruments (e.g., instruments having a musical instrument digital interface (MIDI) output).

The computing device 2400 may include a GPS device 2416 (or corresponding interface circuitry, as discussed above). The GPS device 2416 may be in communication with a satellite-based system and may receive a location of the computing device 2400, as known in the art.

The computing device 2400 may include an other output device 2410 (or corresponding interface circuitry, as discussed above). Examples of the other output device 2410 may include an audio codec, a video codec, a printer, a wired or wireless transmitter for providing information to other devices, or an additional storage device.

The computing device 2400 may include an other input device 2420 (or corresponding interface circuitry, as discussed above). Examples of the other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 2400 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 2400 may be any other electronic device that processes data.

### SELECT EXAMPLES

Example 1 provides an IC device, including: a support structure having a first surface and a second surface opposing the first surface; a first transformer coil over the support structure, the first transformer coil being closer to the second surface than the first surface; a second transformer coil over the support structure, the second transformer coil being closer to the second surface than the first surface; a semiconductor device over or at least partially in the support structure, the semiconductor device coupled to the first transformer coil or the second transformer coil and being closer to the first surface than the second surface; a first via at least partially in the support structure and a second via at least partially in the support structure, where the first via and the second via are connected to the first transformer coil; and a third via at least partially in the support structure and a fourth via at least partially in the support structure, where the third via and the fourth via are connected to the second transformer coil.

Example 2 provides the IC device according to example 1, further including: a power plane over the support structure; a ground plane over the support structure; a first buried power rail at least partially in the support structure, the first buried power rail coupled to the power plane and to the semiconductor device; and a second buried power rail at least partially in the support structure, the second buried power rail coupled to the ground plane and to the semiconductor device.

Example 3 provides the IC device according to example 2, where the first buried power rail or the second buried power rail has a longitudinal axis parallel to the first surface or the second surface.

Example 4 provides the IC device according to example 2 or 3, where the power plane or the ground plane is closer to the second surface than the first surface.

Example 5 provides the IC device according to any of the preceding examples, where the first via or the second via extends between the first surface and the second surface.

Example 6 provides the IC device according to any of the preceding examples, where the first transformer coil includes a portion of a first layer including an electrically conductive material and a portion of a second layer including an electrically conductive material, and the first layer is between the support structure and the second layer.

Example 7 provides the IC device according to any of the preceding examples, where the portion of the first layer is coupled to the portion of the second layer by a via that is closer to the second surface than the first surface.

Example 8 provides an IC structure, including: a support structure having a first surface and a second surface opposing the second surface; a semiconductor device that is closer to the first surface than the second surface; a first layer over the support structure, the first layer including a first electrically conductive material and an alternative pattern of first structures and second structures, where an individual first structure or an individual second structure includes a portion of the first electrically conductive material; a second layer over the support structure and closer to the second surface than the first surface, the second layer including a second electrically conductive material and an alternative pattern of third structures and fourth structures, where an individual third structure or an individual fourth structure includes a portion of the second electrically conductive material; a first transformer coil including the first structures and the third structures; and a second transformer coil including the second structures and the fourth structures, where the first transformer coil and the second transformer coil are coupled to the semiconductor device.

Example 9 provides the IC device according to example 8, where the first layer is closer to the first surface than the second surface.

Example 10 provides the IC device according to example 9, where the first structures are coupled to the third structures by vias, and an individual via extends between the first surface and the second surface, or the second structures are coupled to the fourth structures by vias, and an individual via extends between the first surface and the second surface.

Example 11 provides the IC device according to any one of examples 8-10, where the first layer is closer to the second surface than the first surface.

Example 12 provides the IC device according to example 11, where the first structures are coupled to the third structures by vias over the support structure, or the second structures are coupled to the fourth structures by vias over the support structure.

Example 13 provides the IC device according to any one of examples 8-12, further including a magnetic core over the support structure, where the magnetic core is coupled to the first transformer coil and the second transformer coil.

Example 14 provides the IC device according to any one of examples 8-13, where the first structures are separated from the second structures by an electrical insulator in the first layer, or the third structures are separated from the fourth structures by an electrical insulator in the second layer.

Example 15 provides an IC structure, including: a support structure; a first layer over the support structure, the first layer including an electrically conductive material; a first transformer coil in the first layer, the first transformer coil including a first portion of the electrically conductive material; a second transformer coil in the first layer, the second transformer coil including a second portion of the electrically conductive material, having a first end and a second end, and at least partially enclosed by the first transformer coil; a second layer over the support structure, where the second layer is between the support structure and the first layer; a first elongated structure in the second layer, the first elongated structure including an electrically conductive material and coupled to the first end; and a second elongated structure in the second layer, the second elongated structure including an electrically conductive material and coupled to the second end.

Example 16 provides the IC device according to example 15, where the first elongated structure is coupled to the first end by a via across a portion of the first layer and a portion of the second layer.

Example 17 provides the IC device according to example 16, where the via has a longitudinal axis perpendicular to the first layer or the second layer.

Example 18 provides the IC device according to any one of examples 15-17, further including a semiconductor device over or at least partially in the support structure, where the support structure has a first surface and a second surface, the semiconductor device is closer to the first surface than the second surface and is coupled to the first transformer coil or the second transformer coil, and the second layer is closer to the second surface than the first surface.

Example 19 provides the IC device according to example 18, where the second transformer coil is coupled to the semiconductor device by the first elongated structure and a structure, the structure is in the first layer, the structure includes an electrically conductive material.

Example 20 provides the IC device according to example 19, where a portion of the first transformer coil is between the first end of the second transformer coil and the structure.

Example 21 provides an IC package, including the IC device according to any of the proceeding examples; and a further IC component, coupled to the IC device.

Example 22 provides the IC package according to example 21, where the further IC component includes one of a package substrate, an interposer, or a further IC die.

Example 23 provides the IC package according to example 21 or 22, where the IC device according to any one of examples 1-20 may include, or be a part of, at least one of a memory device, a computing device, a wearable device, a handheld electronic device, and a wireless communications device.

Example 24 provides a n electronic device, including a carrier substrate; and one or more of the IC devices according to any one of examples 1-20 and the IC package according to any one of examples 21-23, coupled to the carrier substrate.

Example 25 provides the electronic device according to example 24, where the carrier substrate is a motherboard.

Example 26 provides the electronic device according to example 24, where the carrier substrate is a PCB.

Example 27 provides the electronic device according to any one of examples 24-26, where the electronic device is a wearable electronic device or handheld electronic device.

Example 28 provides the electronic device according to any one of examples 24-27, where the electronic device further includes one or more communication chips and an antenna.

Example 29 provides the electronic device according to any one of examples 24-28, where the electronic device is an RF transceiver.

Example 30 provides the electronic device according to any one of examples 24-28, where the electronic device is one of a switch, a power amplifier, a low-noise amplifier, a filter, a filter bank, a duplexer, an upconverter, or a downconverter of an RF communications device, e.g., of an RF transceiver.

Example 31 provides the electronic device according to any one of examples 24-30, where the electronic device is a computing device.

Example 32 provides the electronic device according to any one of examples 24-31, where the electronic device is included in a base station of a wireless communication system.

Example 33 provides the electronic device according to any one of examples 24-31, where the electronic device is included in a user equipment device of a wireless communication system.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. An integrated circuit (IC) device, comprising:
a support structure having a first surface and a second surface opposing the first surface;
a first transformer coil over the support structure, the first transformer coil being closer to the second surface than the first surface;
a second transformer coil over the support structure, the second transformer coil being closer to the second surface than the first surface;
a semiconductor device over or at least partially in the support structure, the semiconductor device coupled to the first transformer coil or the second transformer coil and being closer to the first surface than the second surface;
a first via at least partially in the support structure and a second via at least partially in the support structure, wherein the first via and the second via are connected to the first transformer coil; and
a third via at least partially in the support structure and a fourth via at least partially in the support structure, wherein the third via and the fourth via are connected to the second transformer coil.

2. The IC device according to claim 1, further comprising:
a power plane over the support structure;
a ground plane over the support structure;
a first buried power rail at least partially in the support structure, the first buried power rail coupled to the power plane and to the semiconductor device; and
a second buried power rail at least partially in the support structure, the second buried power rail coupled to the ground plane and to the semiconductor device.

3. The IC device according to claim 2, wherein the first buried power rail or the second buried power rail has a longitudinal axis parallel to the first surface or the second surface.

4. The IC device according to claim 2, wherein the power plane or the ground plane is closer to the second surface than the first surface.

5. The IC device according to claim 1, wherein the first via or the second via extends between the first surface and the second surface.

6. The IC device according to claim 1, wherein the first transformer coil includes a portion of a first layer comprising an electrically conductive material and a portion of a second layer comprising an electrically conductive material, and the first layer is between the support structure and the second layer.

7. The IC device according to claim 1, wherein the portion of the first layer is coupled to the portion of the second layer by a via that is closer to the second surface than the first surface.

8. An integrated circuit (IC) structure, comprising:
a support structure having a first surface and a second surface opposing the second surface;
a semiconductor device that is closer to the first surface than the second surface;
a first layer over the support structure, the first layer comprising a first electrically conductive material and an alternative pattern of first structures and second structures, wherein an individual first structure or an individual second structure includes a portion of the first electrically conductive material;
a second layer over the support structure and closer to the second surface than the first surface, the second layer comprising a second electrically conductive material and an alternative pattern of third structures and fourth structures, wherein an individual third structure or an individual fourth structure includes a portion of the second electrically conductive material;
a first transformer coil comprising the first structures and the third structures; and
a second transformer coil comprising the second structures and the fourth structures, wherein the first transformer coil and the second transformer coil are coupled to the semiconductor device.

9. The IC device according to claim 8, wherein the first layer is closer to the first surface than the second surface.

10. The IC device according to claim 9, wherein the first structures are coupled to the third structures by vias, and an individual via extends between the first surface and the second surface, or the second structures are coupled to the fourth structures by vias, and an individual via extends between the first surface and the second surface.

11. The IC device according to claim 8, wherein the first layer is closer to the second surface than the first surface.

12. The IC device according to claim 11, wherein the first structures are coupled to the third structures by vias over the support structure, or the second structures are coupled to the fourth structures by vias over the support structure.

13. The IC device according to claim 8, further comprising a magnetic core over the support structure, wherein the magnetic core is coupled to the first transformer coil and the second transformer coil.

14. The IC device according to claim 8, wherein the first structures are separated from the second structures by an electrical insulator in the first layer, or the third structures are separated from the fourth structures by an electrical insulator in the second layer.

15. An integrated circuit (IC) structure, comprising:
a support structure;
a first layer over the support structure, the first layer comprising an electrically conductive material;
a first transformer coil in the first layer, the first transformer coil comprising a first portion of the electrically conductive material;
a second transformer coil in the first layer, the second transformer coil comprising a second portion of the electrically conductive material, having a first end and a second end, and at least partially enclosed by the first transformer coil;
a second layer over the support structure, wherein the second layer is between the support structure and the first layer;
a first elongated structure in the second layer, the first elongated structure comprising an electrically conductive material and coupled to the first end; and
a second elongated structure in the second layer, the second elongated structure comprising an electrically conductive material and coupled to the second end.

16. The IC device according to claim 15, wherein the first elongated structure is coupled to the first end by a via across a portion of the first layer and a portion of the second layer.

17. The IC device according to claim 16, wherein the via has a longitudinal axis perpendicular to the first layer or the second layer.

18. The IC device according to claim 15, further comprising a semiconductor device over or at least partially in the support structure, wherein the support structure has a first surface and a second surface, the semiconductor device is closer to the first surface than the second surface and is coupled to the first transformer coil or the second transformer coil, and the second layer is closer to the second surface than the first surface.

19. The IC device according to claim 18, wherein the second transformer coil is coupled to the semiconductor device by the first elongated structure and a structure, the structure is in the first layer, the structure comprises an electrically conductive material.

20. The IC device according to claim 19, wherein a portion of the first transformer coil is between the first end of the second transformer coil and the structure.
